(19) United States
(12) Patent Application Publication
(10) Pub. No.: US 2006/0220220 A1
(43) Pub. Date: Oct. 5, 2006

(54) Electronic device and method for fabricating the same

(75) Inventors: Kanae Nakagawa, Kawasaki (JP); Masataka Mizukoshi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/182,009

(22) Filed: Jul. 15, 2005

(30) Foreign Application Priority Data
Mar. 18, 2005 (JP) 2005-79048

(51) Int. Cl. H01L 23/12

(52) U.S. Cl. 257/700

(57) ABSTRACT

The electronic device comprises a first substrate 10; a first electrode 22 formed on one primary surface of the first substrate 10; a first resin layer 32 of a thermosetting resin formed on said one primary surface of the first substrate 10, burying the first electrode 22; a second substrate 12 opposed to said one primary surface of the first substrate 10; a second electrode 24 formed on one primary surface of the second substrate 12 opposed to the first substrate 10, corresponding to the first electrode 22 and jointed to the first electrode 22; and a second thermosetting resin layer 42 formed of a thermosetting resin formed on one primary surface of the second substrate 12, burying the second electrode 24, and adhered to the first resin layer 32. The fist electrodes 22 and the second electrodes 24 can be caused to joint to each other by the shrinkage of the first resin layer 32 and the second resin layer 42. The present invention can provide an electronic device having the first electrodes 22 and the second electrodes 24 surely jointed to each other without deteriorating the reliability.

### CROSS-REFERENCE TO RELATED APPLICATION

This application is based upon and claims priority of Japanese Patent Application No. 2005-79048, filed on Mar. 18, 2005, the contents being incorporated herein by reference.

### BACKGROUND OF THE INVENTION

The present invention relates to an electronic device and a method for fabricating the electronic device, more specifically, an electronic device including electrodes formed on substrates different from each other, which are connected to each other, and a method for fabricating the electronic device.

Recently, as electronic equipments are down sized and lightened, the flip chip mounting technology, which mounts a semiconductor chip facedown on a circuit substrate, is proposed. The flip chip mounting technology, which can make it possible a semiconductor chip to have multi-terminals and, in comparison with the wire bonding, can shorten the wiring delay, is much noted.

In the flip chip bonding, for example, solder bumps are formed in advance on electrodes on a semiconductor chip, and the solder bumps are brought into alignment with electrodes formed on a circuit substrate and then performed solder joint by heating.

In the flip chip bonding, it is important to make the height of the solder bumps uniform. That is, when the height of the solder bumps is very ununiform, the electrodes on the semiconductor chip and the electrodes on the circuit substrate must be brought very near each other so that low ones of the solder bumps can be bonded without failure. In this case, high ones of the solder bumps are excessively collapsed to short-circuit with adjacent ones of the solder bumps. Accordingly, in the flip chip bonding, it is important to make the height of the solder bumps uniform.

Recently, as semiconductor chips are increasingly integrated, the pin number of a semiconductor chip tends to increase, and the pitch of the electrodes tends to be narrow. When the pitch of the electrodes is made small, the height of the solder bumps must be made very uniform.

However, it is very difficult to form the solder bumps, micronized in a very uniform height. For example, in forming the solder bumps by electrolytic plating, electroless plating, solder dipping or others, the height of the solder bumps often disperses by several micrometers to several tens micrometers due to a configuration of the electrodes, an area of the electrodes, the presence or absence of connection to interconnection patterns, etc. When the solder bumps are formed by printing, it is difficult to form the solder bumps, micronized. Thus, it is very difficult to form the solder bumps, micronized in a very uniform height.

Then, technologies which bond the electrodes on a circuit substrate and electrodes on a semiconductor chip with each other without using solder bumps are proposed.

For example, Patent Reference 1 describes that an insulation film of epoxy resin is formed, burying electrodes formed on a circuit substrate, another insulation film of epoxy resin, burying electrodes formed on a semiconductor chip, the surfaces of the electrodes and of the insulation film formed on the circuit substrate are cut with a cutting tool, the surfaces of the electrodes and of the insulation film formed on the semiconductor chip are cut with a cutting tool, and then, the electrodes on the circuit substrate and the electrodes on the semiconductor chip are bonded to each other by pressurization and heating with the insulation film on the circuit substrate and the insulation film on the semiconductor chip jointed to each other.

According to Patent Reference 1, the electrodes on the circuit substrate and the electrodes on the semiconductor chip can be jointed with each other without using solder bumps.

Following references disclose the background art of the present invention.

[Patent Reference 1]

Specification of Japanese Patent Application Unexamined Publication No. 2005-12098

However, in the technique of Patent Reference 1, while the insulation film on the circuit substrate and the insulation film on the semiconductor chip are being jointed with each other by pressurization and heating, voids are formed in the insulation films. When the voids are formed in the insulation films, the insulation films have the volumes increased. The electrodes cannot be connected to each other without applying a very large force to the circuit substrate and the semiconductor chip. When a very large force is applied to the circuit substrate and the semiconductor chip, if fragile inter-layer insulation films are formed on the semiconductor chip, for example, the fragile inter-layer insulation films will be much damaged. Thus, it is difficult to ensure sufficient reliability by the technique described in Patent Reference 1.

### SUMMARY OF THE INVENTION

An object of the present invention is to provide an electronic device which allows electrodes to be connected to each other without failure and impairing the reliability, and a method for fabricating the electronic device.

According to one aspect of the present invention, there is provided an electronic device comprising: a first substrate; a first electrode formed on one primary surface of the first substrate; a first resin layer of a thermosetting resin formed on said one primary surface of the first substrate, burying the first electrode; a second substrate opposed to said one primary surface of the first substrate; a second electrode formed on one primary surface of the second substrate opposed to the first substrate, corresponding to the first electrode and jointed to the first electrode; and a second resin layer of a thermosetting resin formed on said one primary surface of the second substrate, burying the second electrode and adhered to the first resin layer.

According to another aspect of the present invention, there is provided a method for fabricating an electronic device comprising the steps of: forming a first electrode on one primary surface of the first substrate; forming a first resin layer of a thermosetting resin on said one primary surface of the first substrate, burying the first electrode; cutting an upper part of the first electrode and an upper part of the first resin layer with a cutting tool; forming a second electrode on one primary surface of the second substrate, corresponding to the first electrode; forming a second resin layer of a thermosetting resin on said one primary surface of the second substrate, burying the second electrode; cutting an upper part of the second electrode and an upper part of the second resin layer with a cutting tool; making thermal processing with the first resin layer and the second resin layer in tight contact with each other, adhering the first resin layer and the second resin layer to each other and shrinking the first resin layer and the second resin layer to thereby joint the first electrode and the second electrode to each other.

According to the present invention, the first resin layer and the second resin layer are formed of a thermosetting resin which is cured without generating by-products, such as water, alcohol, etc. by thermal processing, whereby the first resin layer and the second resin layer can be shrunk and cured while the generation of voids in the first resin layer and the second resin layer is prevented. Thus, the fist electrodes and the second electrodes can be caused to joint to each other by the shrinkage of the first resin layer and the second resin layer. The first electrodes and the second electrodes are caused to joint to each other by the shrinkage of the first resin layer and the second resin layer, whereby the first electrodes and the second electrodes can be jointed to each other without applying an excessively large force from the outside. Thus, according to the present invention, even when fragile inter-layer insulation films are formed on, e.g., the second substrate, the first electrodes and the second electrodes can be surely jointed without damaging the fragile inter-layer insulation films. The present invention can provide an electronic device having the first electrodes and the second electrodes surely jointed to each other without deteriorating the reliability.

### BRIEF DESCRIPTION OF THE DRAWINGS

FIG. 1 is a sectional view of the electronic device according to a first embodiment of the present invention.

FIGS. 2A to 2D are views of the electronic device according to the first embodiment of the present invention in the steps of the method for fabrication the electronic device, which illustrate the method (Part 1).

FIGS. 3A to 3C are views of the electronic device according to the first embodiment of the present invention in the steps of the method for fabrication the electronic device, which illustrate the method (Part 2).

FIGS. 4A and 4B are views of the electronic device according to the first embodiment of the present invention in the steps of the method for fabrication the electronic device, which illustrate the method (Part 3).

FIGS. 5A and 5B are views of the electronic device according to the first embodiment of the present invention in the steps of the method for fabrication the electronic device, which illustrate the method (Part 4).

FIGS. 6A to 6D are views of the electronic device according to the first embodiment of the present invention in the steps of the method for fabrication the electronic device, which illustrate the method (Part 5).

FIGS. 7A and 7B are views of the electronic device according to the first embodiment of the present invention in the steps of the method for fabrication the electronic device, which illustrate the method (Part 6).

FIGS. 8A and 8B are views of the electronic device according to the first embodiment of the present invention in the steps of the method for fabrication the electronic device, which illustrate the method (Part 7).

FIGS. 9A and 9B are views of the electronic device according to the first embodiment of the present invention in the steps of the method for fabrication the electronic device, which illustrate the method (Part 8).

FIGS. 10A to 10C are views of the electronic device according to the first embodiment of the present invention in the steps of the method for fabrication the electronic device, which illustrate the method (Part 9).

FIGS. 11A and 11B are views of the electronic device according to the first embodiment of the present invention in the steps of the method for fabrication the electronic device, which illustrate the method (Part 10).

FIG. 12 is a view of the electronic device according to the first embodiment of the present invention in the steps of the method for fabrication the electronic device, which illustrate the method (Part 11).

FIGS. 13A and 13B are views of the electronic device according to the first embodiment of the present invention in the steps of the method for fabrication the electronic device, which illustrate the method (Part 12).

FIGS. 14A to 14C are views of the electronic device according to the first embodiment of the present invention in the steps of the method for fabrication the electronic device, which illustrate the method (Part 13).

FIGS. 15A and 15B are views of the electronic device according to the first embodiment of the present invention in the steps of the method for fabrication the electronic device, which illustrate the method (Part 14).

FIG. 16 is a view of the electronic device according to the first embodiment of the present invention in the steps of the method for fabrication the electronic device, which illustrate the method (Part 15).

FIGS. 17A and 17B are views of the electronic device according to the first embodiment of the present invention in the steps of the method for fabrication the electronic device, which illustrate the method (Part 16).

FIGS. 18A and 18B are views of the electronic device according to the first embodiment of the present invention in the steps of the method for fabrication the electronic device, which illustrate the method (Part 17).

FIGS. 19A and 19B are views of the electronic device according to the first embodiment of the present invention in the steps of the method for fabrication the electronic device, which illustrate the method (Part 18).

FIG. 20 is a sectional view of the electronic device according to a second embodiment of the present invention.

FIGS. 21A and 21B are views of the electronic device according to the second embodiment of the present invention in the steps of the method for fabricating the electronic device, which illustrate the method (Part 1).

FIGS. 22A and 22B are views of the electronic device according to the second embodiment of the present invention in the steps of the method for fabricating the electronic device, which illustrate the method (Part 2).

FIGS. 23A and 23B are views of the electronic device according to the second embodiment of the present invention in the steps of the method for fabricating the electronic device, which illustrate the method (Part 3).

FIGS. 24A to 24C are views of the electronic device according to the second embodiment of the present invention in the steps of the method for fabricating the electronic device, which illustrate the method (Part 4).

FIGS. 25A and 25B are views of the electronic device according to the second embodiment of the present invention in the steps of the method for fabricating the electronic device, which illustrate the method (Part 5).

FIGS. 26A and 26B are views of the electronic device according to the second embodiment of the present invention in the steps of the method for fabricating the electronic device, which illustrate the method (Part 6).

FIGS. 27A to 27C are views of the electronic device according to the second embodiment of the present invention in the steps of the method for fabricating the electronic device, which illustrate the method (Part 7).

FIGS. 28A and 28B are views of the electronic device according to the second embodiment of the present invention in the steps of the method for fabricating the electronic device, which illustrate the method (Part 8).

FIGS. 29A and 29B are views of the electronic device according to the second embodiment of the present invention in the steps of the method for fabricating the electronic device, which illustrate the method (Part 9).

FIGS. 30A and 30B are views of the electronic device according to the second embodiment of the present invention in the steps of the method for fabricating the electronic device, which illustrate the method (Part 10).

FIGS. 31A and 31B are views of the electronic device according to the second embodiment of the present invention in the steps of the method for fabricating the electronic device, which illustrate the method (Part 11).

### DETAILED DESCRIPTION OF THE INVENTION

### A First Embodiment

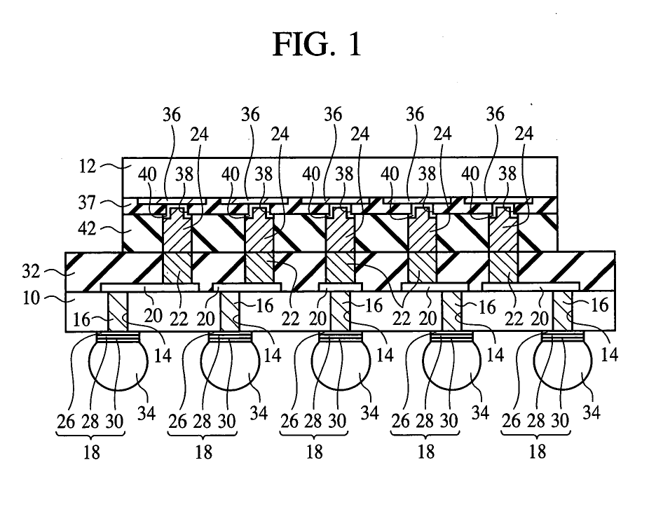

The electronic device according to a first embodiment of the present invention and a method for fabricating the electronic device will be explained with reference to FIGS. 1 to 19B. FIG. 1 is a sectional view of the electronic device according to the present embodiment.

(Electronic Device)

First, the electronic device according to the present embodiment will be explained with reference to FIG. 1.

As illustrated in FIG. 1, in the electronic device according to the present embodiment, a circuit substrate (a first substrate) 10 and a semiconductor substrate (a second substrate) 12 opposed to each other.

Through-holes 14 are formed in the circuit substrate 10. Vias (through-electrodes) 16 of, e.g., copper (Cu) are buried in the through-hole 14. The circuit substrate 10 is, e.g., a silicon substrate or others. The vias 16 are arranged at positions corresponding to outside connection electrodes 18 which will be described later. Generally, the outside connection terminals 18 are arranged at a relatively large pitch so as to ensure the reliability of the flip chip bonding. To this end, the vias 16 are arranged at the relatively large pitch corresponding to the outside connection terminals 18.

On one primary surface of the circuit substrate 10 (the surface opposed to the semiconductor substrate 12), interconnections 20 connected to the vias 16 are formed. The material of the interconnections 20 is, e.g., Cu. The interconnections 20 are for electrically connecting the electrodes 22 and the vias 16 which are located at positions different from each other.

Electrodes 22 are formed on one surfaces of the electrodes 20 (the surface opposed to the semiconductor substrate 12). The electrodes 22 electrically connect electrodes 24 formed on the semiconductor substrate 12 and the interconnections 20 to each other. The electrodes 22 are arranged at the positions corresponding to the electrodes 24 formed on the semiconductor substrate 12. Generally, the electrodes 24 on the semiconductor substrate 12 are arranged at a relatively small pitch. To this end, the electrodes 22 are arranged at the relatively small pitch corresponding to the electrodes 24. The material of the electrodes 22 is, e.g., Cu.

A Cu film 26 is formed on the other primary surface of the circuit substrate 10 (opposite to the surface opposed to the semiconductor substrate 12), connected to the vias 16. The thickness of the Cu film 26 is set at, e.g., 2 μm. A nickel (Ni) film 28 is formed on one surface of the Cu film 26 (opposite to the surface opposed to the semiconductor substrate 12). The thickness of the Ni film 28 is set at, e.g., 1-2 μm. A gold (Au) film 30 is formed on one surface of the Ni film 28 (opposite to the surface opposed to the semiconductor substrate 12). The thickness of the Au film 30 is set at, e.g., 1 μm. The Cu film 26, the Ni film 28 and the Au film 30 form the outside interconnection electrodes 18.

A resin layer (a first resin layer) 32 is formed on one primary surface of the circuit substrate 10 (opposite to the semiconductor substrate 12), burying the electrodes 22.

The resin layer 23 is formed of a thermosetting resin which is cured and shrunk without generating by-products, such as water, alcohol, organic acid, nitrides, etc. Such thermosetting resin is, e.g., a resin formed of mainly benzocyclobutene (BCB) (hereinafter called “BCB resin”). The material of such BCB resin can be, e.g., BCB resin solution (trade name: CYCLOTENE 3022-57) by Dow Chemical Company, or others.

The BCB resin is cured by combing the thermally opened cyclobutene rings with the dienophiles having unsaturated linkage by Diels-Alder reaction. In combining the thermally opened cyclobutene rings with the dienophiles having unsaturated linkage, no polar functional groups participate. Accordingly, the BCB resin can be cured without generating by-products, such as water, alcohol, etc. Accordingly, no voids are formed in the BCB resin due to the vaporization of such by-products. The solvent remaining in the BCB resin is vaporized in advance by thermal processing, whereby no voids are formed by the vaporization of the solvent. The BCB resin, which can be cured without forming voids, can be cured and shrunk without failure without increasing the volume due to voids. Thus, as will be described later, the resin layer 32 and the resin layer 42 are shrunk, whereby the electrodes 22 and the electrodes 24 can be jointed to each other.

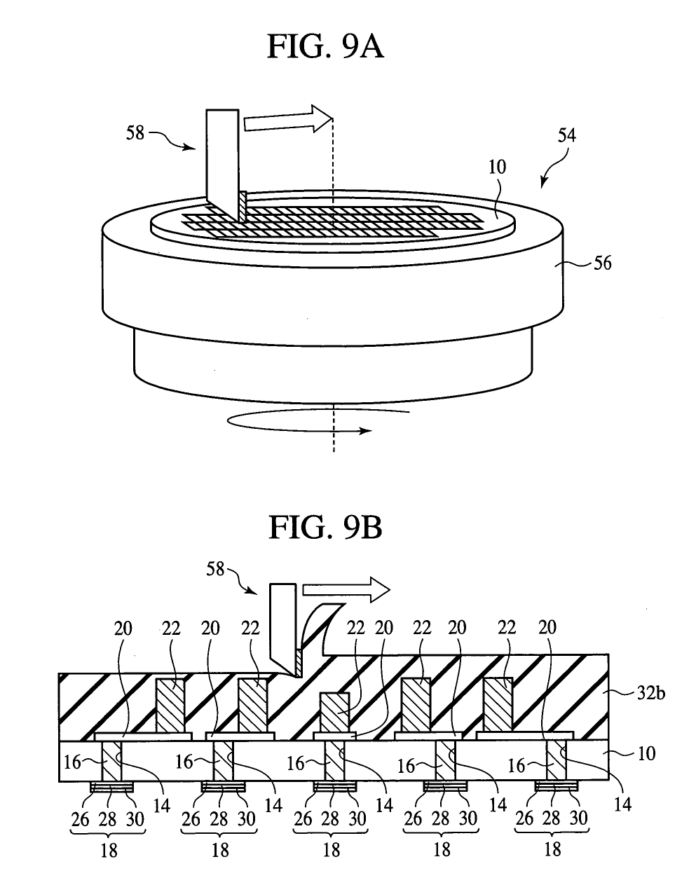

One surfaces of the electrodes 22 (opposed to the semiconductor substrate 12) and one surface of the resin layer 32 (opposed to the semiconductor substrate 12) are cut with a cutting tool 58 (see FIGS. 9A and 9B) of diamond or others, as will be described later. Said one surfaces of the electrodes 22 (opposed to the semiconductor substrate 12) and said surface of the resin layer 32 (opposed to the semiconductor substrate 12), which have been cut with the cutting tool 58, are planarized. Specifically, the difference in the height between said one surfaces of the electrodes 22 (opposed to the semiconductor substrate 12) and said surface of the resin layer 32 (opposed to the semiconductor substrate 12) is, e.g., 100 nm or below.

Solder bumps 34 of, e.g., Sn-based solder are formed on one surfaces of the outside connection electrodes 18 (opposite to the surface opposed to the semiconductor substrate 12).

An integrated circuit (not illustrated) including electronic circuit elements (not illustrated) is formed on one primary surface of the semiconductor substrate 12 (opposed to the circuit substrate 10). That is, on one primary surface of the semiconductor substrate 12 (opposed to the circuit substrate 10), electronic circuit devices, such as active elements, such as transistors, etc. (not illustrated) and/or passive elements, such as capacitors, etc. (not illustrated) are formed. On one primary surface of the semiconductor substrate 12 with such electronic circuit devices formed on (opposed to the circuit substrate 10), a multi-layer interconnection structure of a plurality of inter-layer insulation films and interconnection layers is formed. This multi-layer interconnection structure electrically interconnects the electronic circuit elements (not illustrated).

In FIG. 1, of interconnections forming in a plurality of layers, only the interconnections 36 which are nearest to the electrodes 24 are illustrated.

The interconnections 36 electrically connect the integrated circuit (not illustrated) formed on the semiconductor substrate 12 and the outside to each other and are electrically connected to the electronic circuit elements (not illustrated) via conductor plugs (not illustrated) and interconnections (not illustrated).

The semiconductor substrate 12 is, e.g, a silicon substrate. The material of the interconnections 36 is, e.g., Cu.

On one primary surface of the semiconductor substrate 12 with the interconnections 36 formed on (opposed to the circuit substrate 10), a passivation film 37 of, e.g., polyimide is formed. Contact holes 38 are formed in the passivation film 37 down to the interconnections 36.

In the contact holes 38, a layer film 40 of, e.g., a titanium (Ti) film and a Cu film is formed. In forming electrodes 24 by electroplating on one surface of the layer film 40 (opposed to the circuit substrate 10), the layer film 40 functions as the plating electrode.

The electrodes 24 are formed on one surface of the layer film 40 (opposed to the circuit substrate 10). The electrodes 24 are electrically connected to the electronic circuit elements (not illustrated) formed on the semiconductor substrate 12. The electrodes 24 are for electrically connecting the integrated circuit (not illustrated) formed on the semiconductor substrate 12 and outside to each other. The material of the electrodes 24 is, e.g., Cu.

A resin layer (a second resin layer) 42 is formed on one primary surface of the semiconductor substrate 12 (opposed to the circuit substrate 10), burying the electrodes 24.

The resin layer 42 is formed of, as is the resin layer 32, a thermosetting resin which is cured and shrunk without generating by-products, such as water, alcohol, organic acid, nitrides, etc. The thermosetting resin is, e.g., the BCB resin, as is the material of the resin layer 32. The material of the BCB resin can be, e.g., BCB resin solution (trade name: CYCLOTENE 3022-57) by Dow Chemical Company, or others.

The BCB resin can be cured without generating by-products, such as water, alcohol, etc., as described above. Accordingly, no voids are formed in the BCB resin due to the vaporization of such by-products. The solvent remaining in the BCB resin is vaporized in advance by thermal processing, whereby no voids are formed by the vaporization of the solvent. The BCB resin, which can be cured without forming voids, can be cured and shrunk without failure without increasing the volume due to voids. Thus, as will be described later, the resin layer 32 and the resin layer 42 are shrunk, whereby the electrodes 22 and the electrodes 24 can be jointed to each other.

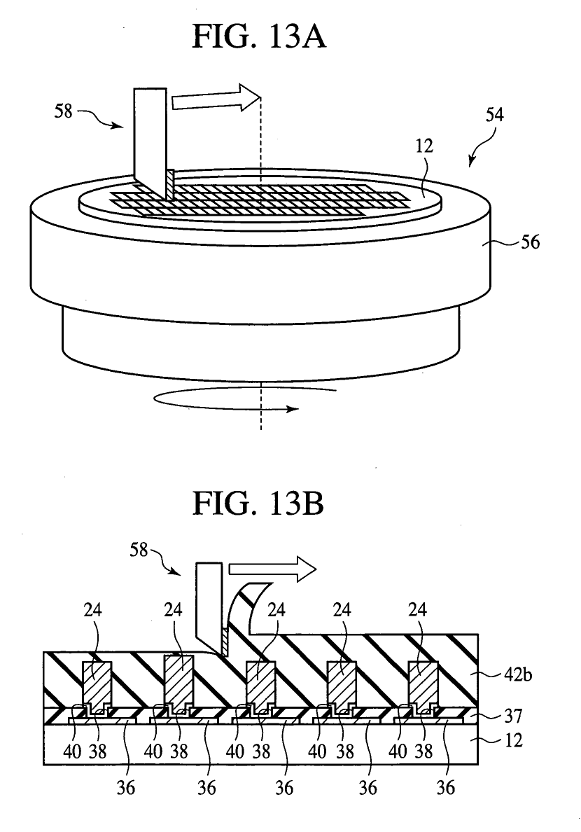

In the illustrated structure, said one surface of the electrodes 24 (opposed to the circuit substrate 10) and said one surface of the resin layer 42 (opposed to the circuit substrate 10) are cut with the cutting tool 58 (see FIGS. 13A and 13B) of diamond or others as will be described later. One surfaces of the electrodes 24 (opposed to the circuit substrate 10) and the surface of the resin layer 42 (opposed to the circuit substrate 10), which have been cut with the cutting tool 58, are planarized. Specifically, the difference in the height between one surfaces of the electrodes 24 (opposed to the circuit substrate 10) and one surface of the resin layer 32 (opposed to the circuit substrate 10) is, e.g., 100 nm or below.

The resin layer 32 formed on the circuit substrate 10 and the resin layer 42 formed on the semiconductor substrate 12 are bonded to each other, as will be described later. The electrodes 22 formed on the circuit substrate 19 and the electrodes 24 formed on the semiconductor substrate 12 are jointed to each other. The resin layer 32 and the resin layer 42 have been subjected to the thermal processing for shrinkage, as will be described later. The resin layer 32 and the resin layer 42, which have been bonded to each other, are shrunk, which joints firm one surfaces of the electrodes 22 (opposed to the semiconductor substrate 12) and one surfaces 24 (opposed to the circuit substrate 10) to each other.

Thus, the electronic device according to the present embodiment is constituted.

The electronic device according to the present embodiment is characterized mainly in that a thermosetting resin which is cured without generating by-products, such as water, alcohol, etc. is used as the material of the resin layers 32, 42.

When phenol resin, epoxy resin, polyimide resin or another resin is used as the material of the resin layers, by-products, such as water, alcohol, organic acid, nitrides, etc., are generated by the thermal processing for curing the resin, and such by-products are a cause for forming voids in the resin layers. When voids are formed in the resin layers, the volumes of the resin layers are increased, which makes it difficult to connect the first electrodes formed on the circuit substrate and the second electrodes formed on the semiconductor substrate to each other without failure. It is an idea to apply a large force to the first electrodes and the second electrodes from the outside. When fragile inter-layer insulation film is formed on the semiconductor substrate, for example, the fragile inter-layer insulation films are much damaged. The application of an excessively large force from the outside to the first electrodes formed on the circuit substrate and the second electrodes formed on the semiconductor substrate is a factor for decreasing the reliability of the electronic device.

In contrast to this, according to the present embodiment, the resin layers 32, 42 are formed of the resin which is cured without generating by-products, such as water, alcohol, etc. by the thermal processing, whereby the resin layers 32, 42 can be shrunk and cured while the formation of voids in the resin layers 32, 42 are prevented. Thus, the electrodes 22 and the electrodes 24 can be caused to joint to each other by the shrinkage of the resin layers 32, 42. The electrodes 22 and the electrodes 24 are caused to joint to each other by the shrinkage of the resin layer 32 and the resin layer 42, whereby the electrodes 22 and the electrodes 24 can be jointed to each other without applying an excessively large force from the outside. Thus, according to the present embodiment, even when fragile inter-layer insulation films (not illustrated) are formed on the semiconductor substrate 12, for example, the electrodes 22 and the electrodes 24 can be surely jointed to each other without damaging the fragile inter-layer insulation films. The electronic device according to the present embodiment can have the electrodes 22 and the electrodes 24 surely jointed to each other without damaging the reliability.

(The Method for Fabricating the Electronic Device)

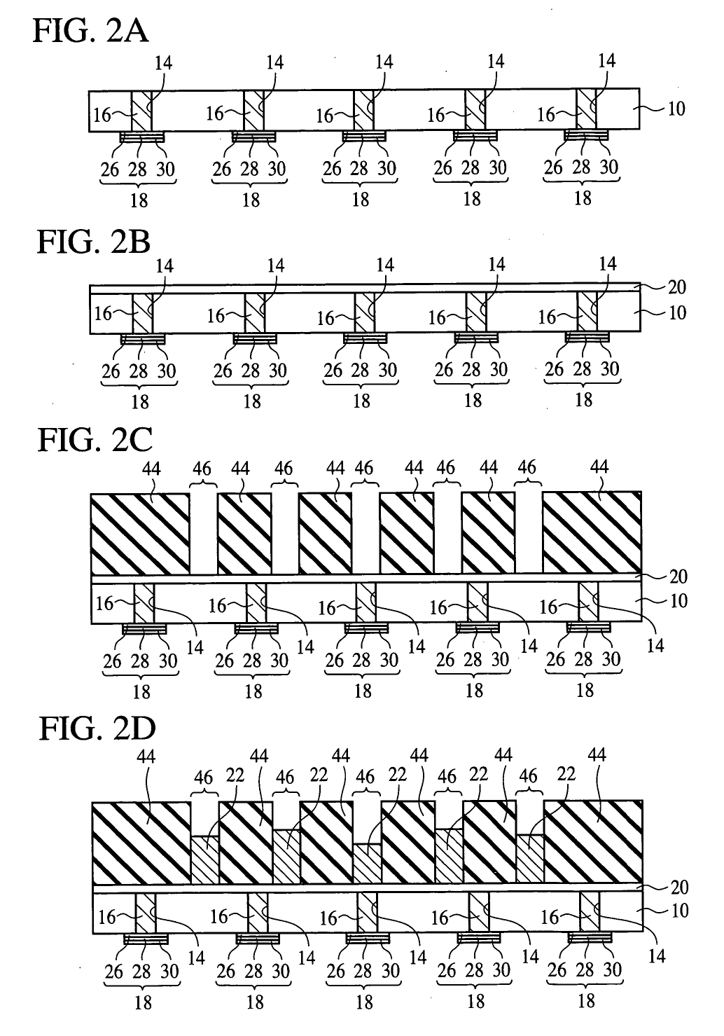

Then, the method for fabricating the electronic device according to the present embodiment will be explained with reference to FIGS. 2A to 19B. FIGS. 2A to 19B are views of the electronic device according to the present embodiment in the steps of the method for fabricating the electronic device, which illustrate the method.

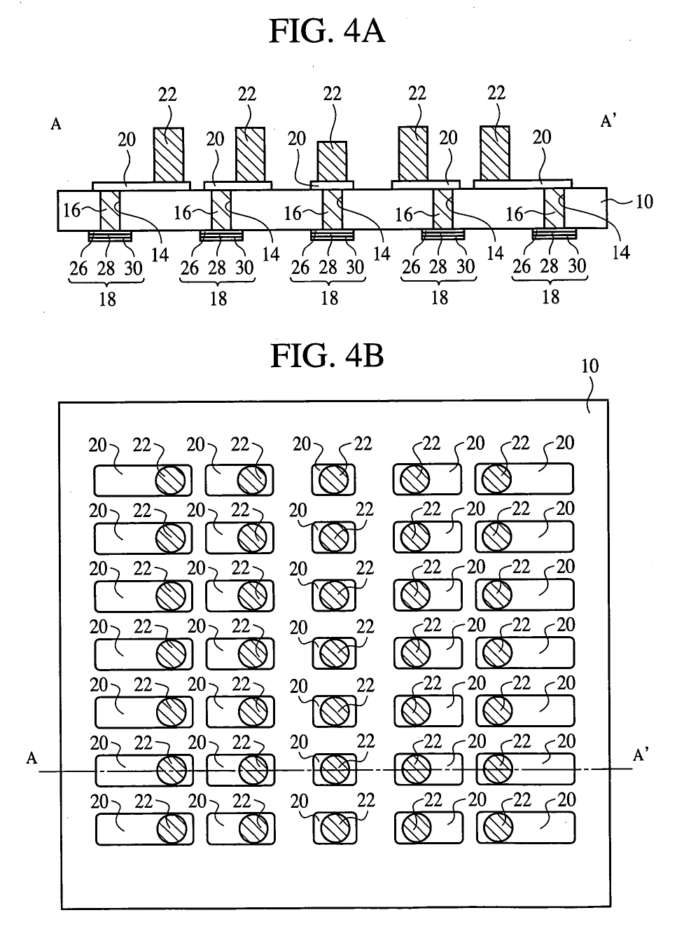

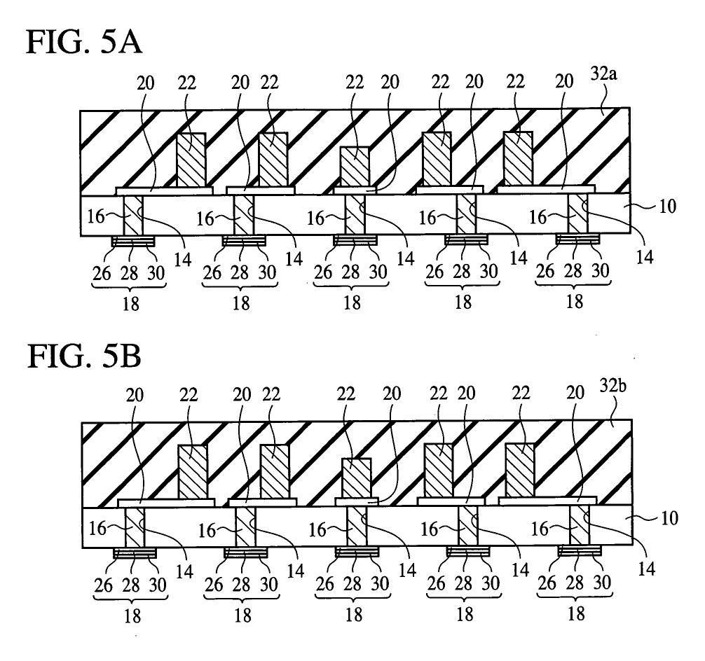

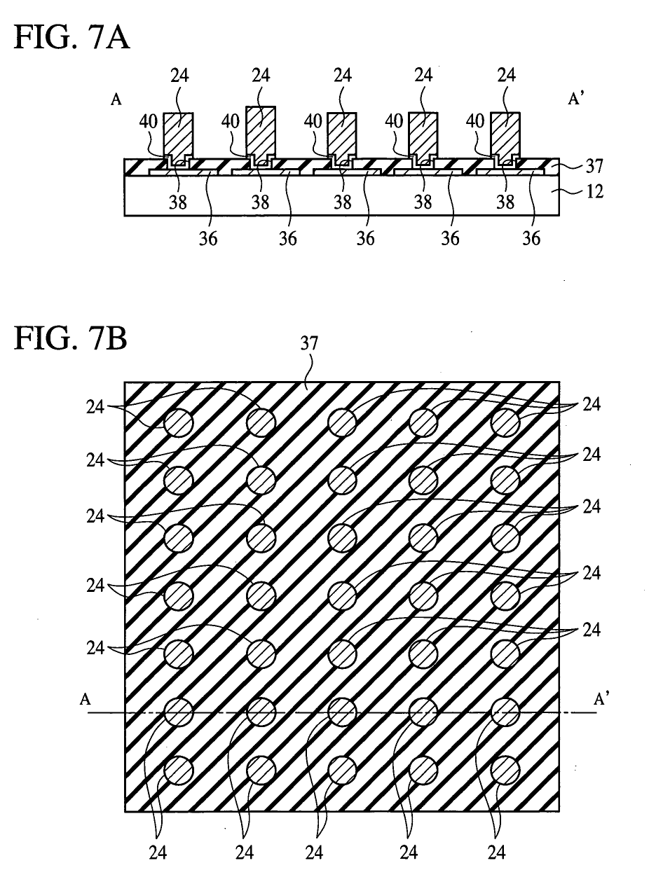

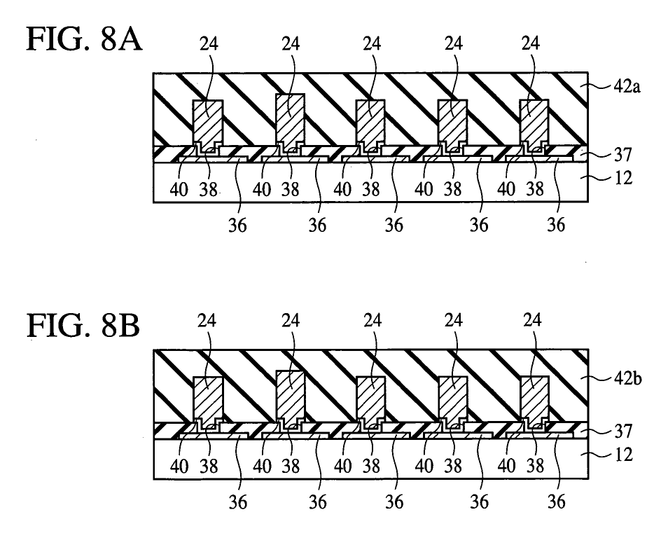

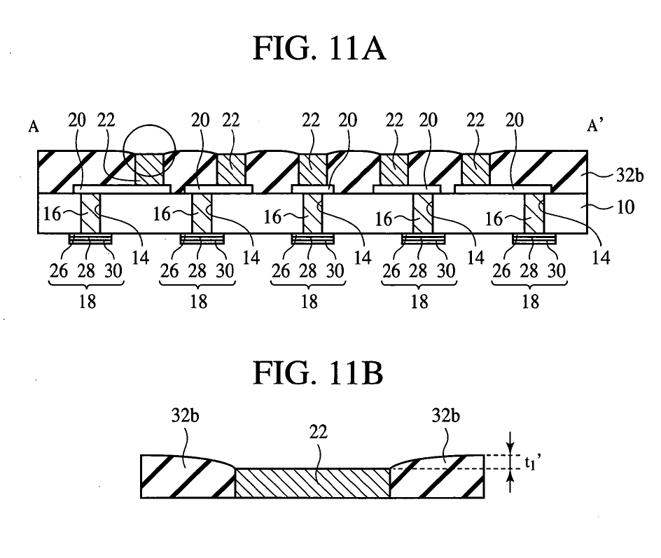

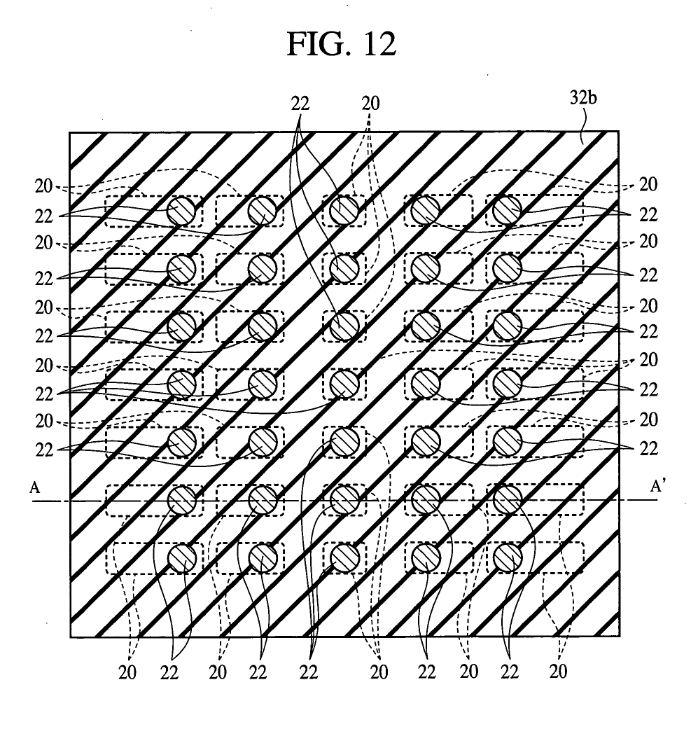

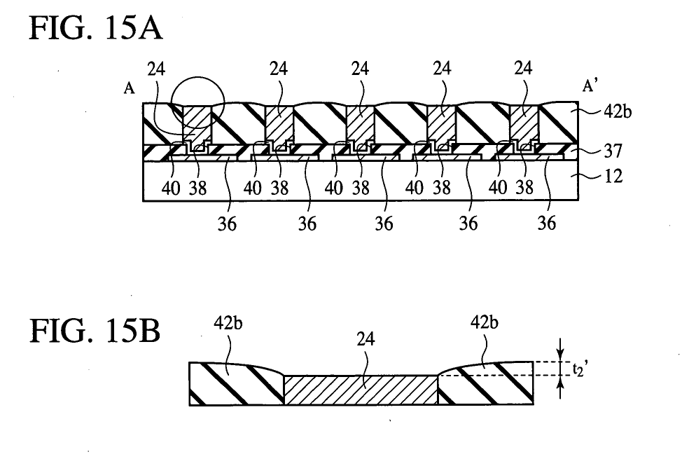

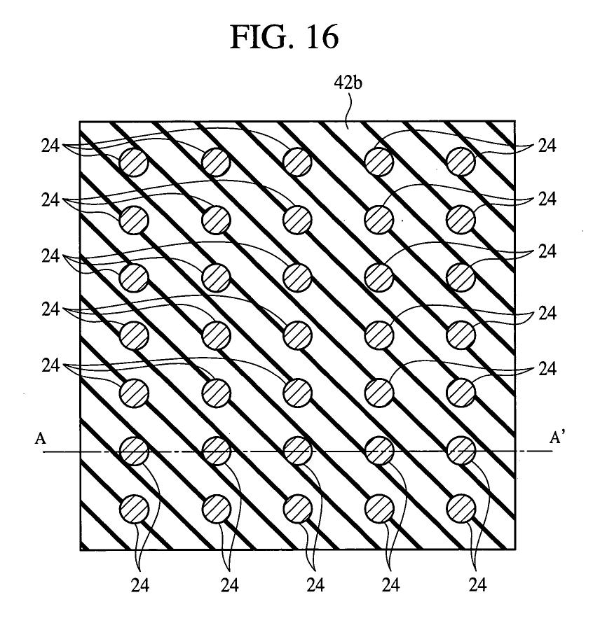

FIG. 2A to FIG. 4A, FIG. 5A to FIG. 7A, FIG. 8A, FIG. 8B, FIG. 9B to FIG. 11B, FIG. 13B to FIG. 15B and FIG. 17A to FIG. 19B are sectional views. FIG. 4B, FIG. 7B, FIG. 12B and FIG. 16 are plan views. FIG. 4A is the sectional view along the line A-A′ in FIG. 4B. FIG. 7A is the sectional view along the line A-A′ in FIG. 7B. FIG. 11A is the sectional view along the line A-A′ in FIG. 12. FIG. 15A is the sectional view along the line A-A′ in FIG. 16. FIG. 9A and FIG. 13A are perspective views.

As illustrated in FIG. 2A, the circuit substrate 10 with the vias 16 and the outside connection electrodes 18, etc. formed on is prepared.

The circuit substrate 10 is not cut in a prescribed size. The circuit substrate 10 is, e.g., a silicon substrate or others.

The vias (through-electrodes) 30 are buried in the through-holes 14 formed in the circuit substrate 10. The vias 16 are formed of, e.g., Cu.

On one primary surface of the circuit substrate 10 (opposite to the surface opposed to the semiconductor substrate 12), the outside connection electrodes 18 are formed, connected to the vias 16. The vias 16 are electrically connected to the outside via the outside connection electrodes 18. To this end, the vias 16 and the outside connection electrodes 18 are arranged corresponding to electrodes (not illustrated) of an outside equipment (not illustrated).

The outside connection electrodes 18 are formed by sequentially laying the Cu film 26, the Ni film 28 and the Au film 30. The film thickness of the Cu film 26 is, e.g., 2 μm, and the film thickness of the Ni film 38 is, e.g., 1-2 μm. The film thickness of the Au film 30 is, e.g., 1 μm.

Then, as illustrated in FIG. 2B, the Cu film 20 is formed on the other entire primary surface of the circuit substrate (opposed to the semiconductor substrate 12) by sputtering and electroplating. The film thickness of the Cu film 20 is, e.g., 2-10 μm.

Next, as illustrated in FIG. 2C, a first photoresist film 44 is formed on the circuit substrate 10.

Then, openings 46 are formed in the first photoresist film 44 by photolithography. The openings 46 are for forming the electrodes 22. To this end, the openings 46 are formed corresponding to the positions where the electrodes 24 on the semiconductor substrate 12 (see FIG. 1).

Then, as illustrated in FIG. 2D, the electrodes 22 of, e.g., Cu are formed in the openings 46 by electroplating. At this time, the electrodes 22 are formed to be higher by about 8 μm than the surface of the circuit substrate 10.

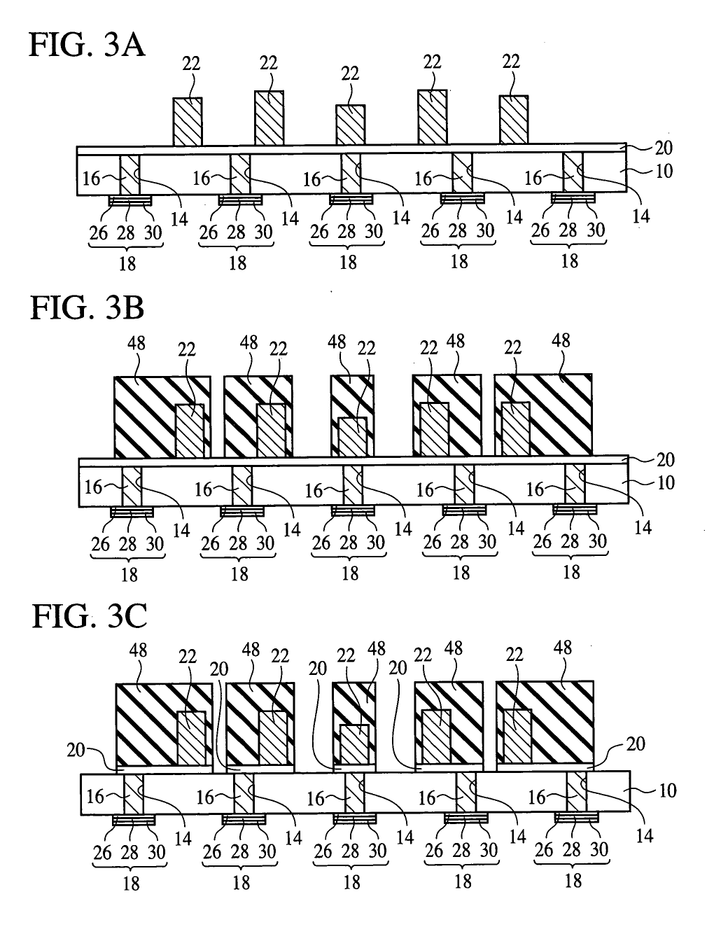

Then, the first photoresist film 44 is released (see FIG. 3A).

Next, a second photoresist film 48 is formed on the circuit substrate 10.

Next, the second photoresist film 48 is patterned into a plane shape of the interconnections 20 (see FIG. 1) by photolithography (see FIG. 3B).

Next, as illustrated in FIG. 3C, with the second photoresist film 48 as the mask, the Cu film 20 is selectively etched off to form the interconnections of the Cu film 20. Then, the second photoresist film 48 is released.

Thus, as illustrated in FIGS. 4A and 4B, the interconnections 20 and the electrodes 22 are formed on the circuit substrate 10. As illustrated in FIG. 4B, the electrodes 22 are formed corresponding to the electrodes 24 (see FIG. 7B) formed on the semiconductor substrate 12.

Then, as illustrated in FIG. 5A, the resin layer (a first resin layer) 32a is formed on the entire surface by, e.g., spin coating. The film thickness of the resin layer 32a is, e.g., about 10 μm. The resin layer 32a can be formed of, e.g., BCB (benzocyclobutene) resin. The material of the BCB resin can be, e.g., BCB resin solution (traded name: CYCLOTENE 3022-57) by Dow Chemical Company, or others. The BCB resin is a thermosetting resin having the characteristic that the BCB resin is liquid before the thermal processing, semi-cured as the thermal processing is advanced to some extent and is completely cured as the thermal processing is further advanced. Conditions for the thermal processing for semi-curing the BCB resin are 180° C. and about 1 hour, and conditions for completely curing the BCB resin are 250° C. and about 1 hour. The viscosity of the BCB resin is about 259 cSt at 25° C.

Thus, the resin layer 32a is formed, burying the electrodes 22. Immediately after the resin layer 32a has been applied, the thermal processing has not been performed yet, and the resin layer 32a is liquid.

Then, the thermal processing is performed under the conditions for semi-curing the resin layer 32a to thereby the non-cured resin layer 32a into the semi-cured resin layer 32b (see FIG. 5B). The degree of cure of the resin layer 32b is preferably 40-80%. The degree of cure of the resin layer 32b is about 50-60% here. The thermal processing temperature is, e.g., about 180° C., and the thermal processing period of time is, e.g., about 1 hour. The atmosphere for the thermal processing is, e.g., N₂ atmosphere.

The thermal processing conditions are not limited to the above. The thermal processing may be performed under conditions under which the degree of cure of the resin layer 32b is 40-80%. For example, when the thermal processing temperature is set high, the thermal processing period of time may be set short. When the thermal processing temperature is set low, the thermal processing period of time may be set long.

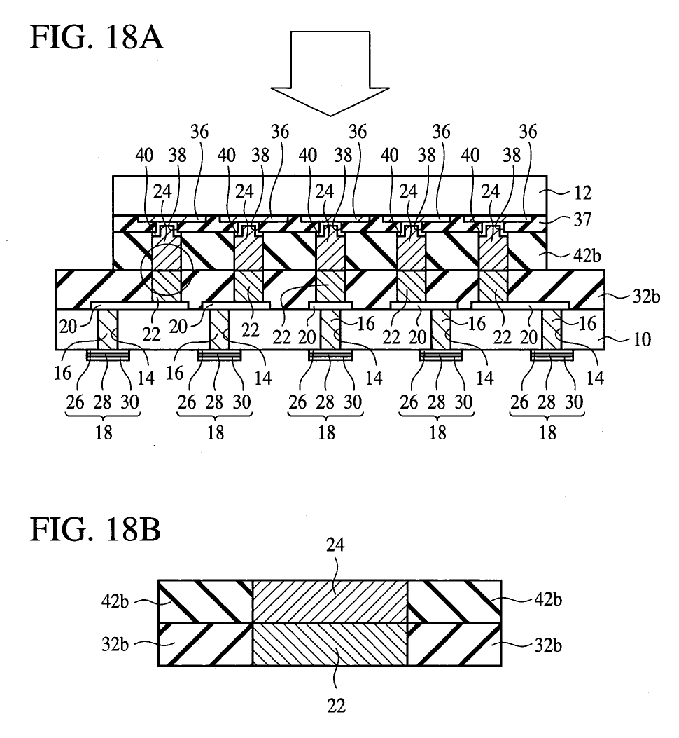

However, the thermal processing temperature must be set at a temperature higher than the boiling point of the solvent of the BCB resin solution. That is, when the thermal processing is made at a temperature lower than the boiling point of the solvent of the BCB resin solution, the solvent of the BCB resin remains in the resin layer 32b. In this case, the solvent remaining in the resin layer 32b is vaporized in the thermal processing of the later step. In the later step thermal processing is made with the resin layer 32b and the resin layer 42b laid the latter on the former (see FIGS. 18A and 18B), and the vaporized solvent is confined in the resin layer 42b. The vaporized solvent confined in the resin layer 32b forms voids in the resin layer 32b. Accordingly, to prevent the formation of voids in the resin layer 32b in the later step thermal processing, the thermal processing temperature must be set at a temperature higher than the boiling temperature of the solvent of the BCB resin solution.

Conditions for the thermal processing are thus set suitably, whereby the degree of cure of the resin layer 32b can be set at 40-80%.

The degree of cure of the resin layer 32b is set at 40-80% for the following reason.

That is, when the degree of cure of the resin layer 32b is set at below 40%, the resin layer 32b is much shrunk in the later step thermal processing. Then, the resin layer 32b and the resin layer 42b are temporarily adhered to each other in the late step thermal processing but are separated from each other as the resin layer 42b is shrunk. In this case, the electrodes 22 and the electrodes 24 cannot be surely jointed to each other. Accordingly, in order to surely adhere the resin layer 32b and the resin layer 42b to each other and surely joint the electrodes 22 and the electrodes 24 to each other, it is necessary to set the degree of cure of the resin layer 32b at 40% or above.

When the degree of cure of the resin layer 32b is set at above 80%, the functional groups present in the resin layer 32b, specifically carbon-carbon double bonds are considerably decreased. Such functional groups (carbon-carbon double bonds) are present in cyclobutene rings and monomers contained in the resin layer 32b. Such functional groups (carbon-carbon double bonds) contribute to adhering the resin layer 32b and the resin layer 42b to each other in the later step. When the functional groups, which contribute to the adhesion are excessively a few, it is difficult to adhere the resin layer 32b and the resin layer 42b to each other in the later step. Furthermore, with the degree of cure of the resin layer 32b is set at above 80%, when the resin layer 32b is cut in the later step, the surface of the resin layer 32b becomes considerably rough. With the surface of the resin layer 32b made considerably rough, it is difficult to adhere the resin layer 32b and the resin layer 42b to each other in the later step. Thus, to surely adhere the resin layer 32b and the resin layer 42b to each other, it is necessary to set the degree of cure of the resin layer 32b at 80% or below.

For the above-described reason, it is preferable to set the degree of cure of the resin layer 32b at 40-80%.

The degree of cure of the resin layer 32b can be given by analyzing the infrared absorption spectra with an FT-IR (Fourier Transform Infrared Spectrophotometer).

When the resin layer 32b is formed of the BCB resin, the cyclobutene rings decrease as the cure advances. Accordingly, the degree of cure can be given by measuring intensities of the components of the infrared absorption spectrum, which correspond to the cyclobutene rings.

That is, the resin layer which has not been subjected to the thermal processing is measured by the Fourier transform infrared spectrophotometer (FT-IR) to give infrared absorption spectra for the degree of cure of 0%. The intensity P₁ of the spectrum component of the infrared absorption spectra for the degree of cure of 0%, which corresponds to the cyclobutene rings is given.

On the other hand, the completely cured resin layer is measured with the Fourier transform infrared spectrophotometer (FT-IR) to obtain the infrared absorption spectra for the degree of cure of 100%. The intensity P₂ of the spectrum component of the infrared absorption spectrum for the degree of cure of 100%, which corresponds to the cyclobutene rings is given.

The semi-cured resin layer 32b is measured with the Fourier transform infrared spectrophotometer (FT-IR) to give the infrared absorption spectra of the semi-cured resin layer 32b. The intensity of P₃ of the spectrum component of the infrared absorption spectra for the semi-cured resin layer 32b, which corresponds to the cyclobutene rings is given.

Then, the degree of cure S of the semi-cured resin layer 32b is given by
S=[(P₃−P₁)/(P₂−P₁)]×100(%).

The degree of cure of the resin layer 32b is given based on intensities of the spectrum components of the cyclobutene rings here. However, the spectrum component used in computing the degree of cure of the resin layer 32b is not essentially the spectrum component corresponding to the cyclobutene rings.

When the resin layer 32b is formed of the BCB resin, as the cure advances, the cylcobutnee rings are decreased while the tetrahydronaphthalene rings increase. Accordingly, intensities of the spectrum components of the infrared absorption spectra, which correspond to the tetrahydronaphthalene rings are measured, whereby the degree of cure of the resin layer 32b can be also given.

That is, the resin layer which has not been subjected to the thermal processing is measured by the Fourier transform infrared spectrophotometer (FT-IR) to give infrared absorption spectra for the degree of cure of 0%. The intensity P₄ of the spectrum component of the infrared absorption spectra for the degree of cure of 0%, which corresponds to the tetrahydronaphthalene rings is given.

On the other hand, the completely cured resin layer is measured with the Fourier transform infrared spectrophotometer (FT-IR) to obtain the infrared absorption spectra for the degree of cure of 100%. The intensity P₅ of the spectrum component of the infrared absorption spectrum for the degree of cure of 100%, which corresponds to the tetrahydronaphthalene rings is given.

The semi-cured resin layer 32b is measured with the Fourier transform infrared spectrophotometer (FT-IR) to give the infrared absorption spectrum of the semi-cured resin layer 32b. The intensity of P₆ of the spectrum component of the infrared absorption spectra for the semi-cured resin layer 32b, which corresponds to the tetrahydronaphthalene rings is given.

Then, the degree of cure S of the semi-cured resin layer 32b is given by
S=[(P₄−P₆)/(P₄−P₅)]×100 (%).

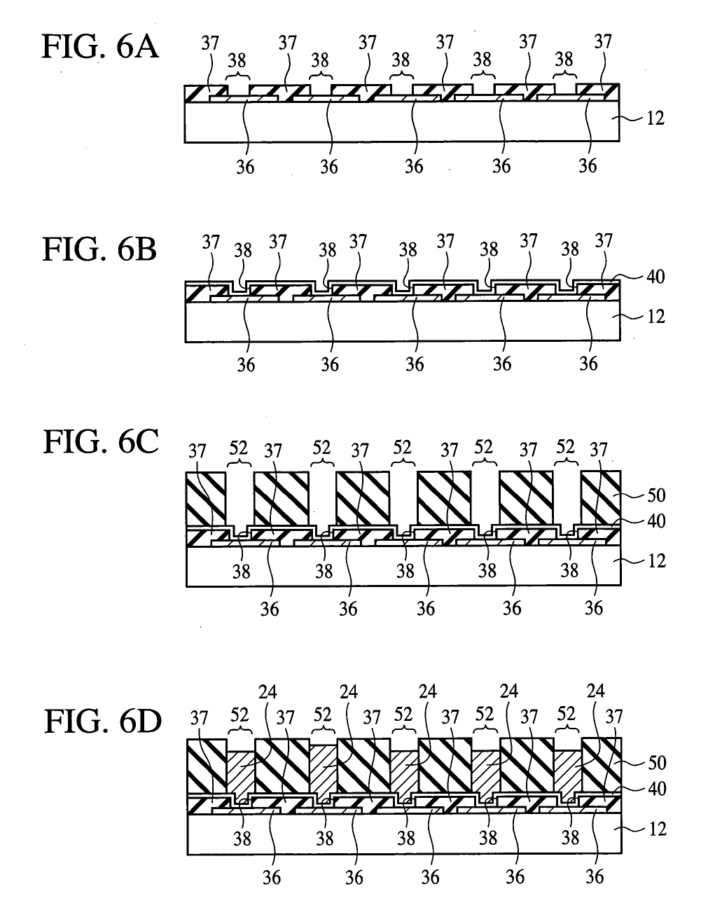

On the other hand, as illustrated in FIG. 6A, the semiconductor substrate 12 with an integrated circuit (not illustrated) including electronic circuit elements (not illustrated) formed on is prepared.

The semiconductor substrate 12 is not cut in a chip size, i.e., in a wafer. The semiconductor substrate 12 is, e.g., a silicon substrate.

On the semiconductor substrate 12, a plurality of inter-layer insulation films and interconnection layers are formed, and the multi-layer interconnection structure is formed (not illustrated). However, in FIG. 6A, the uppermost interconnection 36b alone is illustrated.

Such interconnections 36 are for connecting electrically the integrated circuit formed on the semiconductor substrate 12 and the outside. Such interconnections 36 are electrically connected to the electronic circuit elements via the conductor plugs (not illustrated) and/or interconnections (not illustrated).

The interconnections 36 are formed of, e.g., Cu or others.

On the semiconductor substrate 12 with the interconnections 36 formed on, the passivation film 37 of, e.g., polyimide is formed. The contact holes 38 are formed in the passivation film 37 down to the interconnections 36.

Then, as illustrated in FIG. 6B, a Ti film and a Cu film are sequentially laid on the entire surface by, e.g., sputtering to form the layer film 40. The film thickness of the Ti film is, e.g., 100-300 nm, and the film thickness of the Cu film is, e.g., 200 nm-1 μm.

The photoresist film 50 is formed on the semiconductor substrate 12.

Then, the openings 52 are formed in the photoresist film 50 by photolithography (see FIG. 6C). The openings 52 are for forming the electrodes 24. To this end, the openings 52 are formed at positions corresponding to the positions where the electrodes 22 (see FIG. 4B) on the circuit substrate 10 are formed.

Then, as illustrated in FIG. 6D, the electrodes 24 of, e.g., Cu are formed in the openings 52 by, electroplating. At this time, the electrodes 24 are formed to be higher by, e.g., about 8 μm than the surface of the semiconductor substrate 12. Then, the photoresist film 50 is removed.

Then, as illustrated in FIGS. 7A and 7B, with the electrodes 24 as the mask, the exposed parts of the layer film 40 are etched off.

Thus, the electrodes 24, etc. are formed on one primary surface of the semiconductor substrate 12 (opposed to the circuit substrate 10). As illustrated in FIG. 7B, the electrodes 24 are formed corresponding to the electrodes 22 (see FIG. 4B) formed on the circuit substrate 10.

Then, as illustrated in FIG. 8A, the resin layer (the second resin layer) 42a is formed on the entire surface by, e.g., spin coating. The resin layer 42a is formed of, e.g., BCB (benzocyclobutene) resin. The material of the BCB resin can be, e.g., BCB resin solution (trade name: CYCLOTENE 3022-57) by Dow Chemical Company. As described above, the BCB resin is a thermosetting resin having the curing characteristic that the resin is liquid before the thermal processing, is semi-cured as the cure advances to some extent by the thermal processing and is cured as the thermal processing is further advanced. As described above, thermal processing conditions for semi-curing the BCB resin are 180° C. and about 1 hour, and thermal processing conditions for completely curing the BCB resin are 250° C. and about 1 hour. The film thickness of the resin layer 42a is, e.g., about 10 μm.

Thus, the resin layer 42a is formed, burying the electrodes 24. Immediately after the resin layer 42a has been applied, the resin layer 42a has not yet been subjected to the thermal processing and is liquid.

Next, the thermal processing is made under conditions for semi-curing the resin layer 42a, whereby the non-cured resin layer 42a is cured into the semi-cured resin layer 42b (see FIG. 8B). Preferably, the degree of cure of the resin layer 42b is 40-80%. The degree of cure of the resin layer 42b is 50-60% here. The thermal processing temperature is, e.g., about 180° C., and the thermal processing period of time is, e.g., about 1 hour.

The thermal processing conditions are not limited to the above. The thermal processing may be performed under conditions which make the degree of cure of the resin 42b about 40-80%. For example, when the thermal processing temperature is set high, the thermal processing period of time may be set short. The thermal processing period of time may be set long when the thermal processing temperature is set low.

However, the thermal processing temperature must be set at a temperature higher than the boiling point of the solvent of the BCB resin solution. That is, when the thermal processing is made at a temperature lower than the boiling point of the solvent of the BCB resin solution, the solvent of the BCB resin remains in the resin layer 42b. In this case, the solvent remaining in the resin layer 42b is vaporized in the thermal processing of the later step. In the later step thermal processing is made with the resin layer 32b and the resin layer 42b laid the latter on the former (see FIG. 16), and the vaporized solvent is confined in the resin layer 42b. The vaporized solvent confined in the resin layer 42b forms voids in the resin layer 42b. Accordingly, to prevent the formation of voids in the resin layer 42b in the later step thermal processing, the thermal processing temperature must be set at a temperature higher than the boiling temperature of the solvent of the BCB resin solution.

Conditions for the thermal processing are thus set suitably, whereby the degree of cure of the resin layer 42b can be set at 40-80%.

The degree of cure of the resin layer 42b is set at 40-80% for the same reason for setting the degree of cure of the resin layer 32b at 40-80%.

That is, when the degree of cure of the resin layer 42b is set at below 40%, the resin layer 42b is much shrunk in the later step thermal processing. Then, the resin layer 32b and the resin layer 42b are temporarily adhered to each other in the later step thermal processing, but as the resin layer 42b is shrunk, the resin layer 32 band the resin layer 42b are separated from each other. In this case, the electrodes 22 and the electrodes 24 cannot be surely jointed to each other. Accordingly, to surely adhere the resin layer 32b and the resin layer 42b to each other while surely jointing the electrodes 22 and the electrodes 24 to each other, it is necessary to set the degree of cure of the resin layer 42b at 40% or above.

When the degree of cure of the resin layer 42b is set at above 80%, the functional groups present in the resin layer 42b, specifically carbon-carbon double bonds are considerably deceased. Such functional groups (carbon-carbon double bonds) are present in cyclobutene rings and monomers contained in the resin layer 42b. Such functional groups (carbon-carbon double bonds) contribute to adhering the resin layer 32b and the resin layer 42b to each other in the later step. When the functional groups, which contribute to the adhesion are extremely a few, it is difficult to adhere the resin layer 32b and the resin layer 42b to each other in the later step. Furthermore, with the degree of cure of the resin layer 42b is set at above 80%, when the resin layer 42b is cut in the later step, the surface of the resin layer 42b becomes considerably rough. With the surface of the resin layer 42b made considerably rough, it is difficult to adhere the resin layer 32b and the resin layer 42b to each other in the later step. Thus, to surely adhere the resin layer 32b and the resin layer 42b to each other, it is necessary to set the degree of cure of the resin layer 42b at 80% or below.

For the above-described reason, it is preferable to set the degree of cure of the resin layer 42b at 40-80%.

The degree of cure of the resin layer 42b can be given by the same method as the method for giving the degree of cure of the resin layer 32b. That is, the degree of cure of the resin layer 42b can be given by analyzing the infrared absorption spectra with the Fourier transform infrared spectrophotometer (FT-IR).

Then, as illustrated in FIG. 9A, the circuit substrate 10 is fixed to a chuck table 56 of an ultra-precision lathe 54 by vacuum suction.

FIG. 9A is a perspective view of the circuit substrate fixed to the ultra-precision lathe. The circuit substrate 10 is fixed to the chuck table 56 at the backside thereof, i.e., the surface where the electrodes 22, etc. are not formed.

The chuck table 56 is for fixing an object-to-be-processed, such as a substrate or others when the substrate or others are processed.

Preferably, a pin chuck is used when the circuit substrate 10 is fixed to the chuck table 56.

A plurality of outside connection electrodes 18 are formed on the backside of the circuit substrate 10. The thickness of the outside connection terminals 18 is as thin as several micrometers. This permits the circuit substrate 10 to be fixed to the chuck table 56 by vacuum suction with good repeatability.

Next, as illustrated in FIG. 9B, while the circuit substrate 10 is being rotated, the upper parts of the electrodes 22 and the upper part of the resin layer 32b are cut with the cutting tool 58 of diamond. At this time, the rough cut is continued until the height of one surface of the resin layer 32b (opposed to the resin layer 42b formed on the semiconductor substrate 12) becomes higher by about 5 μm than one primary surface of the circuit substrate 10 (opposed to the semiconductor substrate 12).

Conditions for roughly cutting the upper parts of the electrodes 22 and the upper part of the resin layer 32b are as exemplified below.

The rake of the cutting tool 58 is, e.g., 0 degrees. The rake is an angle formed by a plane perpendicular to the cutting surface of an object-to-be-cut, and a front surface (the rake face) of the cutting tool blade, that is forward in the direction of advance of the cutting tool. Generally, as the rake angle is larger, the cut is better. However, the blade is more damaged, and the life of the blade tends to become shorter.

The rotation number of the chuck table 56 is, e.g., about 2000 rpm. In this case, the cutting speed is, e.g., about 20 m/second.

The cut amount of the cutting tool 58 is, e.g., about 2-3 μm. As described above, the cut amount is a cut depth of the cutting tool 58 at the time of a cut.

The feed speed of the cutting tool 58 is, e.g., 20 μm/rotation. The feed speed is an advance speed of the cutting tool in the radial direction (i.e., the direction interconnecting one point on the outer peripheral edge of the chuck table 56 and the center of the rotation).

The thickness of the resin layer 32b before cut is about 10 μm, but the cut amount by the cutting tool 58 is, e.g., about 2-3 μm. When the cut is made until the height of one surface of the resin layer 32b (opposed to the resin layer 42b formed on the semiconductor substrate 12) becomes higher by about 5 μm than one primary surface of the circuit substrate 10 (opposed to the semiconductor substrate 12), the thickness of the cut part of the resin layer 32b is larger than the cut amount of the cutting tool 58. The upper part of the resin layer 32b is cut a plurality of times to thereby to make the height of one surface of the resin layer 32b (opposed to the resin layer 42b formed on the semiconductor substrate 12) by about 5 μm than one primary surface of the circuit substrate 10 (opposed to the semiconductor substrate 12).

When the upper parts of the electrodes 22 and the upper part of the resin layer 32b are cut with the cutting tool 58, some large force is applied by the cutting tool 58 to the electrodes 22 and the resin layer 32b. While the upper part of the resin layer 32b is being cut, a force is applied not only in the direction horizontal to one surface of the resin layer 32b (opposed to the resin layer 42b formed on the semiconductor substrate 12), but also in the direction perpendicular to one surface of the resin layer 32b (opposed to the resin layer 42b formed on the semiconductor substrate 12). Accordingly, the resin layer 32b is cut while being compressed and deformed to some extent. After the cut, the resin layer 32b which has been compressed and deformed is restored to some extent. On the other hand, the electrodes 22, which are formed of a metal, such as Cu or another, are not substantially compressed and deformed while being cut. Accordingly, the height of one surface of the resin layer 32b (opposed to the resin layer 42b formed on the semiconductor substrate 12) after cut is larger than the height of one surfaces of the electrodes 22 (opposed to the electrodes 24 formed on the semiconductor substrate 12) after cut.

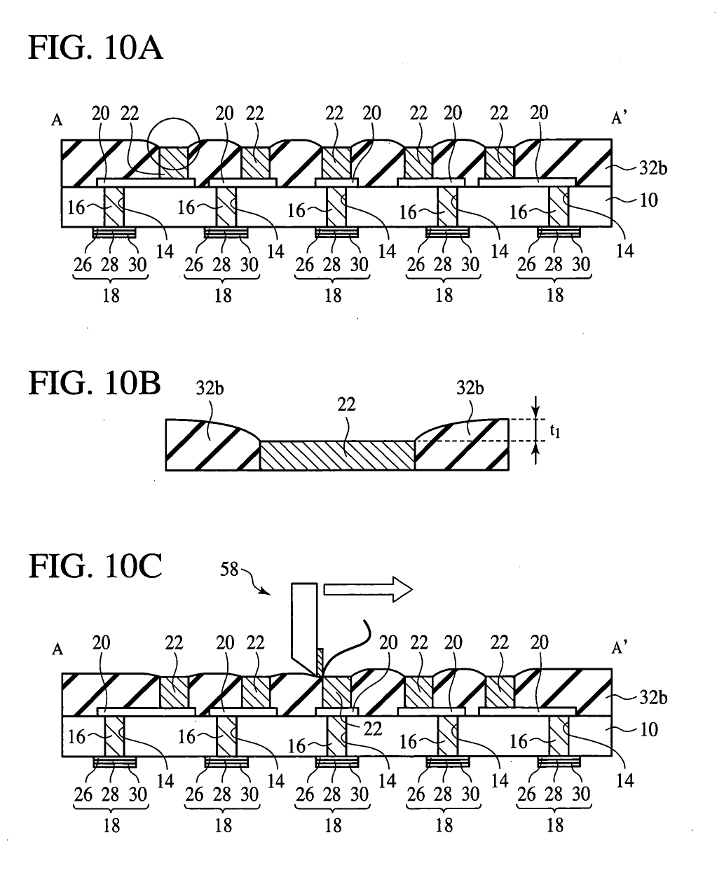

Immediately after the rough cut, as illustrated in FIGS. 10A and 10B, the difference t₁ between the height of one surface of the resin layer 32b (opposed to the resin layer 42b formed on the semiconductor substrate 12) and the height of one surfaces of the electrodes 22 (opposed to the electrodes 24 formed on the semiconductor substrate 12) is about hundreds nm, which is relatively larger.

FIG. 10B is an enlarged sectional view of the part circled in FIG. 10A.

When the difference t₁ between the height of one surface of the resin layer 32b (opposed to the resin layer 42b formed on the semiconductor substrte 12) and the height of one surfaces of the electrodes 22 (opposed to the electrodes 24 formed on the semiconductor substrate 12) is thus relatively large, even though the resin layer 42b is cured and shrunk by the later step thermal processing, one surface of the resin layer 32b (opposed to the resin layer 42b formed on the semiconductor substrate 12) is remains higher than one surfaces of the electrodes 22 (opposed to the electrodes 24 formed on the semiconductor substrate 12), which makes it impossible to joint the electrodes 22 and the electrodes 24 to each other.

To avoid this, the rough cut is followed by finish cut so that the difference t₁ between the height of one surface of the resin layer 32b (opposed to the resin layer 42b formed on the semiconductor substrate 12) and the height of one surfaces of the electrodes 22 (opposed to the electrodes 24 formed on the semiconductor substrate 12) becomes a suitable value.

Conditions for finish cutting the upper parts of the electrodes 22 and the upper part of the resin layer 32b are as exemplified below.

The rake angle of the cutting tool 58, the rotation number of the chuck table 56 and the feed speed of the cutting tool 58 for the finish cut are the same as those for the rough cut of the resin layer 32b. It is not necessary to change this setting for the finish cut, which follows the rough cut.

The cut amount of the cutting tool 58 is, e.g., 0 nm. The cut amount of the cutting tool 58 is set so small, so that the difference t₁ between the height of one surface of the resion layer 32b (opposed to the resin layer 42b formed on the semiconductor substrate 12) and the height of one surfaces of the electrodes 22 (opposed to the surfaces of the electrodes 24 formed on the semiconductor substrate 12) can be suitably small.

However, the cut amount of the cutting tool 58 is not essentially 0 nm. For example, the cut amount of the cutting tool 58 may be set at about 10-100 nm.

As illustrated in FIGS. 11A and 11B, even the finish cut does not make the difference t₁′ between the height of one surface of the resin layer 32b (opposed to the resin layer 42b formed on the semiconductor substrate 12) and the height of one surfaces of the electrodes 22 (opposed to the surfaces of the electrodes 24 formed on the semiconductor substrate 12) zero. This is because the resin layer 32b is compressed and deformed to some extent in the finish cut, and the resin layer 32b which has been compressed and deformed by the finish cut is restored to some extent.

FIG. 11B is an enlarged sectional view of the circled part in FIG. 11A.

When the compressive modulus of elasticity of the object to be cut is E, the thickness of the object to be cut is L, and a force to be applied perpendicularly to the object-to-be-cut is F, the difference t₁′ between the height of one surface of the resin layer 32b (opposed to the resin layer 42b formed on the semiconductor substrate 12) and the height of one surface of the electrodes 22 (opposed to the electrodes 24 formed on the semiconductor substrate 12) is
t₁′=(F×L)/E.

The compressive modulus of elasticity is a force per a unit area required to compress a material to a thickness of zero (actually impossible).

The compressive modulus of elasticity E of the BCB resin 32b is about 7.1 Gpa when the BCB resin 32a is semi-cured by the thermal processing of 180° C. and 1 hour. In cutting the BCB resin 32b, the force F applied perpendicularly to one surface of the BCB resin 32b (opposed to the resin layer 42b formed on the semiconductor substrate 12) is about 55 MPa. When the thickness L of the resin layer 32b in the finish polish is about 5 μm, the difference t₁′ between the height of one surface of the resin layer 32b (opposed to the resin layer 42b formed on the semiconductor substrate 12) and the height of the one surfaces of the electrodes 22 (opposed to the electrodes 24 formed on the semiconductor substrate 12) is about 39 nm.

The difference t₁′ between one surface of the resin layer 32b (opposed to the resin layer 42b formed on the semiconductor substrate 12) and the height of one surfaces of the electrodes 22 (opposed to the electrodes 24 formed on the semiconductor substrate 12) is not essentially limited to about 39 nm. The difference t₁′ between the height of one surface of the resin layer 32b (opposed to the resin layer 42b formed on the semiconductor substrate 12) and the height of one surfaces of the electrodes 22 (opposed to the electrodes 24 formed on the semiconductor substrate 12) may be suitably set to be in the range of 0-100 nm.

The difference t₁′ between the height of one surface of the resin layer 32b (opposed to the resin layer 42b formed on the semiconductor substrate 12) and the height of one surfaces of the electrodes 22 (opposed to the electrodes 24 formed on the semiconductor substrate 12) is set at 0-100 nm for the following reason.

That is, when the difference t₁′ between one surface of the resin layer 32b (opposed to the resin layer 42b formed on the semiconductor substrate 12) and the height of one surfaces of the electrodes 22 (opposed to the electrodes 24 formed on the semiconductor substrate 12) is above 100 nm, as described above, even the resin layer 32b is cured and shrunk by the later step thermal processing, the height of one surface of the resin layer 32b (opposed to the resin layer 42b formed on the semiconductor substrate 12) is higher than the height of one surfaces of the electrodes 22 (opposed to the electrodes 24 formed on the semiconductor substrate 12), which makes it impossible to joint the electrodes 22 and the electrodes 24 to each other.

On the other hand, the difference t₁′ between the height of one surface of the resin layer 32b (opposed to the resin layer 42b formed on the semiconductor substrate 12) and the height of one surfaces of the electrodes 22 (opposed to the electrodes 24 formed on the semiconductor substrate 12) is 0 nm or below, in the later step thermal processing, the resin layer 32b and the resin layer 42b are shrunk before being surely adhered to each other, which makes it difficult to surely adhere the resin layer 32b and the resin layer 42b to each other.

For this reason, it is important that the difference t₁′ between the height of one surface of the resin layer 32b (opposed to the resin layer 42b formed on the semiconductor substrate 12) and the height of one surfaces of the electrodes 22 (opposed to the surfaces of the electrodes 24 formed on the semiconductor substrate 12) is set at 0-100 nm.

To cut the upper part of the resin layer 32b and the upper parts of the electrodes 22 it is important to cut them so that the ten-point height of irregularities Rz of the surface of the resin layer 32b is 0.1 μm or below.

The ten-point height of irregularities Rz is given by extracting a roughness curve by a reference length in the direction of its average line, summing an average value of the absolute values of altitudes of the highest peak to the fifth peak and an average value of the absolute values of altitudes of the lowest valley to the fifth valley measured in the direction of the depth ratio from the average line of the extracted part, and expressing the sum in micrometer (μm) (refer to JIS B 0601-1994). That is, the ten-point height of irregularities Rz is the difference between the average of the five highest peaks from to the mean line and the average depth to the five deepest valleys from the mean line.

The resin layer 32b is cut so that the ten-point height of irregularities of the surface of the resin layer 32b is 0.1 μm or below, because when the ten-point height of irregularities Rz of the surface of the resin layer 32b is above 0.1 μm, it is not easy to adhere the resin layer 32b and the resin layer 42b to each other in the later step.

To surely adhere the resin layer 32b and the resin layer 42b to each other, it is very important to cut the resin layer 32b so that the ten-point height of irregularities Rz of the surface of the resin layer 32b becomes 0.1 μm or below.

When fins are formed on the electrodes 22 in the cut, there is risk that the fins may short-circuit the neighboring or adjacent electrodes 22.

Accordingly, it is preferable to set the cut conditions suitably not to form fins on the electrodes 22 in the cut.

Thus, the upper parts of the electrodes 22 and the upper part of the resin layer 32b are cut (see FIGS. 11A to 12).

It is also possible that with the circuit substrate 10 fixed, a wheel (not illustrated) with the cutting tool 58 mounted on is rotated for the cut (not illustrated).

Then, as illustrated in FIG. 13A, the semiconductor substrate 12 is fixed to the chuck table 56 of the ultra-precision lathe 54 by vacuum suction. FIG. 13A is a perspective view of the semiconductor substrate fixed to the ultra-precision lathe.

The semiconductor substrate 12 is fixed to the chuck table 56 at the underside, i.e., the surface of the semiconductor substrate 12 without the electrodes 24, etc. formed on. It is preferable to use a pin chuck (not illustrated) to fix the semiconductor substrate 12 to the chuck table 56.

Then, as illustrated in FIG. 13B, with the semiconductor substrate 12 being rotated, the upper parts of the electrodes 24 and the upper part of the resin layer 42b are cut with the cutting tool 58 of diamond. At this time, the rough cut is made until the height of one surface of the resin layer 42b (opposed to the resin layer 32b formed on the circuit substrate 10) becomes higher by about 5 μm than one primary surface of the semiconductor substrate 12 (opposed to the circuit substrate 10).

Conditions for making the rough cut on the upper parts of the electrodes 24 and the upper part of the resin layer 42b are as exemplified below.

The rake angle of the cutting tool 58 is, e.g., 0 degree.

The rotation number of the chuck table 56 is, e.g., about 3000 rpm. At this time, the cut speed is, e.g., about 30 m/second.

The cut amount of the cutting tool 58 is, e.g., about 2-3 μm/rotation.

The feed speed of the cutting tool 58 is, e.g., 20 μm/rotation.

The film thickness of the resin layer 42b before cut is, e.g., about 10 μm, but the cut amount of the cutting tool 58 is, e.g., about 2-3 μm. When the cut is made until one surface of the resin layer 42b (opposed to the resin layer 32b formed on the circuit substrate 10) is higher by about 5 μm than one primary surface of the semiconductor substrate 12 (opposed to the circuit substrate 10), the thickness of the part of the resin layer 42b to be cut is larger than the cut amount of the cutting tool 58. The upper part of the resin layer 42b is cut a plurality of times to thereby make the height of one surface of the resin layer 42b (opposed to the resin layer 32b formed on the circuit substrate 10) higher by about 5 μm than one primary surface (opposed to the circuit substrate 10) of the semiconductor substrate 12.

When the upper parts of the electrodes 24 and the upper part of the resin layer 42b are cut, a considerably large force is applied to the electrodes 24 and the resin layer 42b by the cutting tool 58. While the upper part of the resin layer 42b is being cut, the force is applied not only horizontally to one surface of the resin layer 42b (opposed to the resin layer 32b formed on the circuit substrate 10), but also vertically to one surface of the resin layer 42b (opposed to the resin layer 32b formed on the circuit substrate 10). Accordingly, the resin layer 42b is cut, compressed and deformed to some extent. After the cut, the resin layer 42b which has been compression deformed by the cutting tool in the cut is restored so some extent. On the other hand, the electrodes 24, which are formed of a metal, such as Cu or others, are not substantially compression deformed. Accordingly, one surface of the resin layer 42b (opposed to the resin layer 32b formed on the circuit substrate 10) after cut becomes higher than the surface of one surfaces of the electrodes 24 (opposed to the electrodes 22 formed on the circuit substrate 10) after cut.

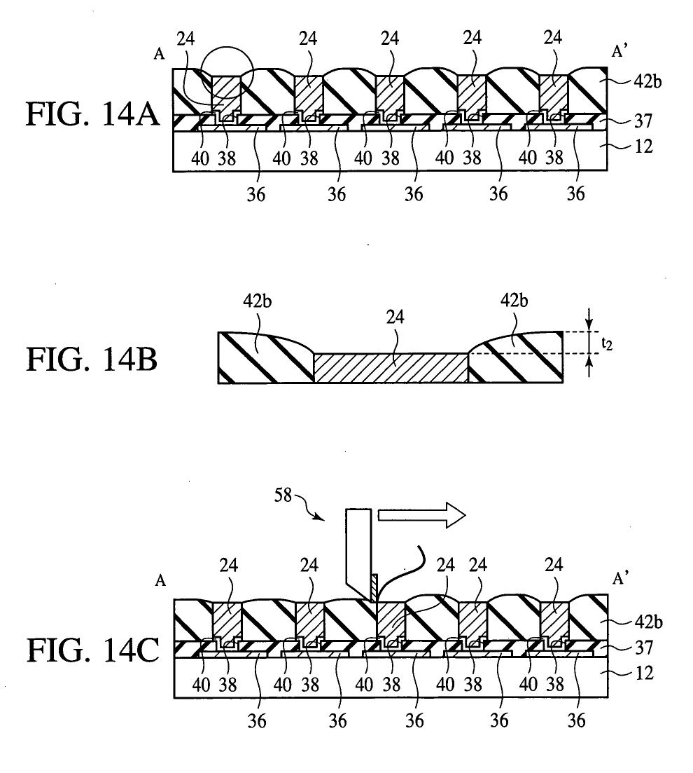

Immediately after the rough cut, as illustrated in FIGS. 14A and 14B, the difference t₂ between the height of one surface of the resin layer 42b (opposed to the resin layer 32b formed on the circuit substrate 10) and the height of one surfaces of the electrodes 24 (opposed to the electrodes 22 formed on the circuit substrate 10) becomes relatively larger by about hundreds nm.

FIG. 14B is an enlarged sectional view of the circled part in FIG. 14A.

When the difference t₂ between the height of one surface of the resin layer 42b (opposed to the resin layer 32b formed on the circuit substrate 10) and the height of one surfaces of the electrodes 24 (opposed to the electrodes 22 formed on the circuit substrate 10) is such relatively large, even when the resin layer 42b is cured and shrunk by the later step thermal processing, the height of one surface of the resin layer 42b (opposed to the resin layer 32b formed on the circuit substrate 10) remains higher than the height of one surfaces of the electrodes 24 (opposed to the electrodes 22 formed on the circuit substrate 10), which makes it impossible to joint the electrodes 22 and the electrodes 24 to each other.

To avoid this, the rough cut is followed by the finish cut so that the difference t₂ between the height of one surface of the resin layer 42b (opposed to the resin layer 32b formed on the circuit substrate 10) and the height of one surfaces of the electrodes 24 (opposed to the electrodes 22 formed on the circuit substrate 10) can be a suitable value (see FIG. 14C).

Conditions for the finish cut for the upper parts of the electrodes 24 and the upper part of the resin layer 42b are as exemplified below.

For the finish cut, the rake angle of the cutting tool 58, the rotation number of the chuck table 56 and the feed speed of the cutting tool 58 are the same as those for the rough cut of the resin layer 42b. The finish cut follows the rough cut, and the setting does not have to be changed.

The cut amount of the cutting tool 58 is, e.g., 0 nm. The cut amount is set so low so that the difference t₂ between the height of one surface of the resin layer 42b (opposed to the resin layer 32b formed on the circuit substrate 10) and the height of one surfaces of the electrodes 24 (opposed to the electrodes 22 formed on the circuit substrate 10) is made suitably small.

The cut amount of the cutting tool 58 is not limited to 0 nm. For example, the cut amount of the cutting tool 58 may be set at about 10-100 nm.

As illustrated in FIGS. 15A and 15B, even the finish cut does not make zero the difference t₂′ between the height of one surface of the resin 42b (opposed to the resin layer 32b formed on the circuit substrate 10) and the height of one surfaces of the electrodes 24 (opposed to the electrodes 22 formed on the circuit substrate 10). This is because also in the finish cut, the resin layer 42b is compressed and deformed to some extent, and the resin layer 42b which has been compressed and deformed in the finish cut is restored to some extent after the cut.

FIG. 15B is an enlarged sectional view of the part circled in FIG. 15A.

When the compressive modulus of elasticity of the object to be cut is E, the thickness of the object to be cut is L, and a force to be applied perpendicularly to the object-to-be-cut is F, the difference t₂′ between the height of one surface of the resin layer 42b (opposed to the resin layer 32b formed on the circuit substrate 10) and the height of one surface of the electrodes 24 (opposed to the electrodes 22 formed on the circuit substrate 10) is
t₂′=(F×L)/E.

The compressive modulus of elasticity E of the BCB resin 42b is about 7.1 GPa when the BCB resin 42a is semi-cured by the thermal processing of 180° C. and 1 hour. In cutting the BCB resin 42b, the force F applied perpendicularly to one surface of the BCB resin 42b (opposed to the resin layer 32b formed on the circuit substrate 10) is about 55 MPa. When the thickness L of the resin layer 42b in the finish polish is about 5 μm, the difference t₂′ between the height of one surface of the resin layer 42b (opposed to the resin layer 32b formed on the circuit substrate 10) and the height of the one surfaces of the electrodes 24 (opposed to the electrodes 22 formed on the circuit substrate 10) is about 39 nm.

The difference t₂′ between one surface of the resin layer 42b (opposed to the resin layer 32b formed on the circuit substrate 10) and the height of one surfaces of the electrodes 24 (opposed to the electrodes 22 formed on the circuit substrate 10) is not essentially limited to about 39 nm. The difference t₂′ between the height of one surface of the resin layer 42b (opposed to the resin layer 32b formed on the circuit substrate 10) and the height of one surfaces of the electrodes 24 (opposed to the electrodes 22 formed on the circuit substrate 10) may be suitably set to be in the range of 0-100 nm.

The difference t₂′ between the height of one surface of the resin layer 42b (opposed to the resin layer 32b formed on the circuit substrate 10) and the height of one surfaces of the electrodes 24 (opposed to the electrodes 22 formed on the circuit substrate 10) is set at 0-100 nm for the following reason.

That is, when the difference t₂′ between one surface of the resin layer 42b (opposed to the resin layer 32b formed on the circuit substrate 10) and the height of one surfaces of the electrodes 24 (opposed to the electrodes 22 formed on the circuit substrate 10) is 100 nm or above, as described above, even the resin layer 42b is cured and shrunk by the later step thermal processing, the height of one surface of the resin layer 42b (opposed to the resin layer 32b formed on the circuit substrate 10) is higher than the height of one surfaces of the electrodes 24 (opposed to the electrodes 22 formed on the circuit substrate 10), which makes it impossible to joint the electrodes 22 and the electrodes 24 to each other.

On the other hand, the difference t₂′ between the height of one surface of the resin layer 42b (opposed to the resin layer 32b formed on the circuit substrate 10) and the height of one surfaces of the electrodes 24 (opposed to the electrodes 22 formed on the circuit substrate 10) is below 0 nm, in the later step thermal processing, the resin layer 32b and the resin layer 42b are shrunk before being surely adhered to each other, which makes it difficult to surely adhere the resin layer 32b and the resin layer 42b to each other.

For this reason, it is important that the difference t2′ between the height of one surface of the resin layer 42b (opposed to the resin layer 32b formed on the circuit substrate 10) and the height of one surfaces of the electrodes 24 (opposed to the surfaces of the electrodes 22 formed on the circuit substrate 10) is set at 0-100 nm.

To cut the upper part of the resin layer 42b and the upper parts of the electrodes 24 it is important to cut them so that the ten-point height of irregularities Rz of the surface of the resin layer 42b is 0.1 μm or below.

The resin layer 42b is cut so that the ten-point height of irregularities of the surface of the resin layer 42b is 0.1 μm or below, because when the ten-point height of irregularities Rz of the surface of the resin layer 42b is above 0.1 μm, it is not easy to adhere the resin layer 32b and the resin layer 42b to each other in the later step.

To surely adhere the resin layer 32b and the resin layer 42b to each other, it is very important to cut the resin layer 42b so that the ten-point height of irregularities Rz of the surface of the resin layer 42b becomes 0.1 μm or below.

When fins are formed on the electrodes 24 in the cut, there is risk that the fins may short-circuit the neighboring or adjacent electrodes 24.

Accordingly, it is preferable to set the cut conditions suitably not to form fins on the electrodes 24 in the cut.

Thus, the upper parts of the electrodes 24 and the upper part of the resin layer 42b are cut (see FIGS. 15A to 16).

It is also possible that with the semiconductor substrate 12 fixed, a wheel (not illustrated) with the cutting tool 58 mounted on is rotated for the cut (not illustrated).

Next, the circuit substrate 10 is cut in a prescribed size with a thin blade of diamond particles, etc. connected with a binder (not illustrated).

The semiconductor substrate 12 is cut in a chip size with a thin blade of diamond particles, etc. connected with a binder (not illustrated).

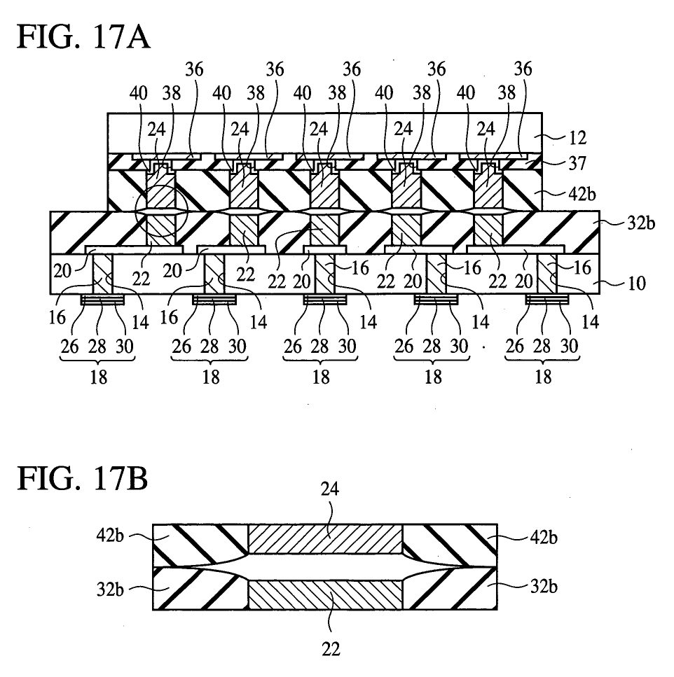

Next, as illustrated in FIGS. 17A and 17B, the semiconductor substrate 12 and the circuit substrate 10 are opposed to each other. At this time, the semiconductor substrate 12 and the circuit substrate 10 are opposed to each other with the electrodes 24 of the semiconductor substrate 12 and the electrodes 22 of the circuit substrate 10 opposed to each other. FIG. 17B is an enlarged sectional view of the part circled in FIG. 17A.

Then, thermal processing is performed with the electrodes 24 of the semiconductor substrate 12 and the electrodes 22 of the circuit substrate 10, and the resin layer 42b of the semiconductor substrate 12 and the resin layer 32b of the circuit substrate being in tight contact respectively with each other by a pressure applied to the circuit substrate 10 and to the semiconductor substrate 12 from the outside (see FIGS. 18A and 18B). FIG. 18B is an enlarged sectional view of the part circled in FIG. 18A.

An oven (thermal processing system), for example, is used for the thermal processing. The thermal processing temperature is, e.g., 250° C. The thermal processing period of time is, e.g., about 1 hour. The pressure is, e.g., about 10 kPa. The thermal processing under these conditions surely adheres the resin layer 32b and the resin layer 42b to each other. The resin layer 32b and the resin layer 42b are respectively shrunk. The resin layer 32b and the resin layer 42b are brought into contact with each other while being respectively shrunk, and the shrinkage of the resin layer 32b and the resin layer 42b causes the electrodes 22 and the electrodes 24 to tightly contact with each other. The semi-cured resin layers 32b, 42b become completely cured resin layers 32, 42. Because of the completely cured resin layers 32, 42, which have been sufficiently shrunk, the electrodes 22 and the electrodes 24 are never separated from each other even when the application of the pressure is stopped.

The electrodes 22 and the electrodes 24 are caused to tightly contact with each other by the shrinkage of the resin layers 32, 42, which makes it unnecessary to apply a large pressure to the circuit substrate 10 and the semiconductor substrate 12 from the outside. Accordingly, even when fragile inter-layer insulation films are formed on, e.g., the semiconductor substrate 12, the electrodes 22 and the electrodes 24 can be adhered to each other without damaging the fragile inter-layer insulation films.

The thermal processing temperature is set at 250° C., and the thermal processing period of time is set at 1 hour here. However, the thermal processing temperature and the thermal processing period of time are not limited to them. When the thermal processing temperature is set high, the thermal processing period of time may be short. Specifically, when the thermal processing temperature is set at about 300° C., the thermal processing period of time may be about 3 minutes. When the thermal processing temperature is set low, the thermal processing period of time may be set long. Specifically, when the thermal processing temperature is set at about 200° C., the thermal processing period of time may be set at about 7-8 hours.

However, when the thermal processing temperature is set high, the resin layers 32, 42 do not have often good film quality. When the thermal processing temperature is set low, the thermal processing takes much time. When the film quality of the resin films 32, 42, throughputs, etc. are considered, preferably, the thermal processing temperature is set at about 250° C., and the thermal processing period of time is set at about 1 hour.

The pressure applied to the circuit substrate 10 and to the semiconductor substrate 12 is set at about 10 kPa here. However, the pressure to be applied to the circuit substrate 10 and to the semiconductor substrate 12 is not limited to about 10 kPa. The pressure may be set suitably at a pressure in the range of 1 kPa-100 kPa.

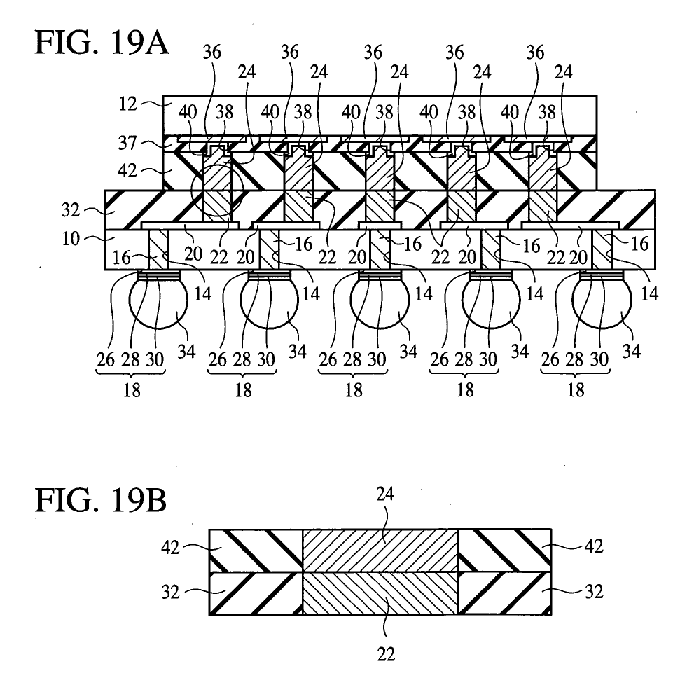

Then, the solder bumps 34 of, e.g., Sn-based solder are formed on one surfaces of the outside connection electrodes 18 (opposite to the surface opposed to the semiconductor substrate 12) (see FIGS. 19A and 19B). FIG. 19B is an enlarged sectional view of the part circled in FIG. 19A.

Thus, the electronic device according to the present embodiment is fabricated.

The method for fabricating the electronic device according to the present embodiment is characterized mainly in that the resin layer 32b and the resin layer 42b are formed of a thermosetting resin which is cured without generating by-products, such as water, alcohol, organic acid, nitrides, etc.

According to the present embodiment, the resin layers 32b, 42b are formed of a thermosetting resin which is cured without generating by-products, such as water, alcohol, etc., whereby the semi-cured resin layers 32b, 42b can be made the completely cured resin layers 32, 42 while the formation of voids in the resin layers 32b, 42b is prevented. According to the present embodiment, the resin layers 32b, 42b never have the volumes increased by voids, and accordingly, the resin layers 32b, 42b can be surely cured and shrunk. Thus, according to the present embodiment, the electrodes 22 and the electrodes 24 can be caused to contact to each other by the shrinkage of the resin layer 32b and the resin layer 42b. According to the present embodiment, the electrodes 22 and the electrodes 24 are caused to contact to each other by the shrinkage of the resin layer 32b and the resin layer 42b, whereby the electrodes 22 and the electrodes 24 can be jointed to each other without applying an extremely high pressure from the outside. Accordingly, even when fragile inter-layer insulation film are formed on, e.g., the semiconductor substrate 12, the electrodes 22 and the electrodes 24 can be surely jointed to each other without damaging the fragile inter-layer insulation films. Thus, the present embodiment can fabricate the electronic device having the electrodes 22 and the electrodes 24 surely jointed to each other without damaging the reliability.

### A Second Embodiment

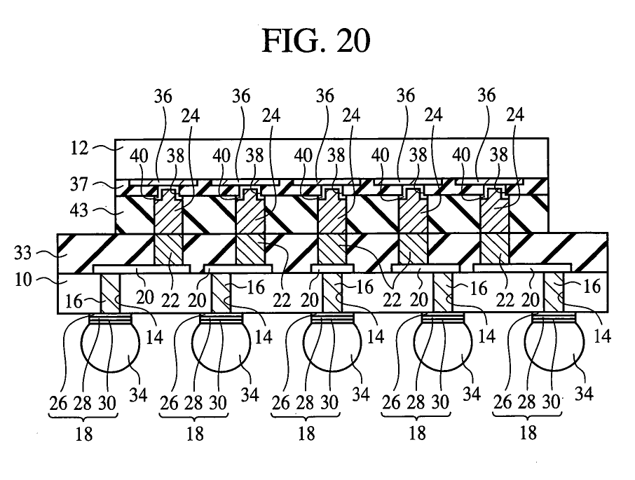

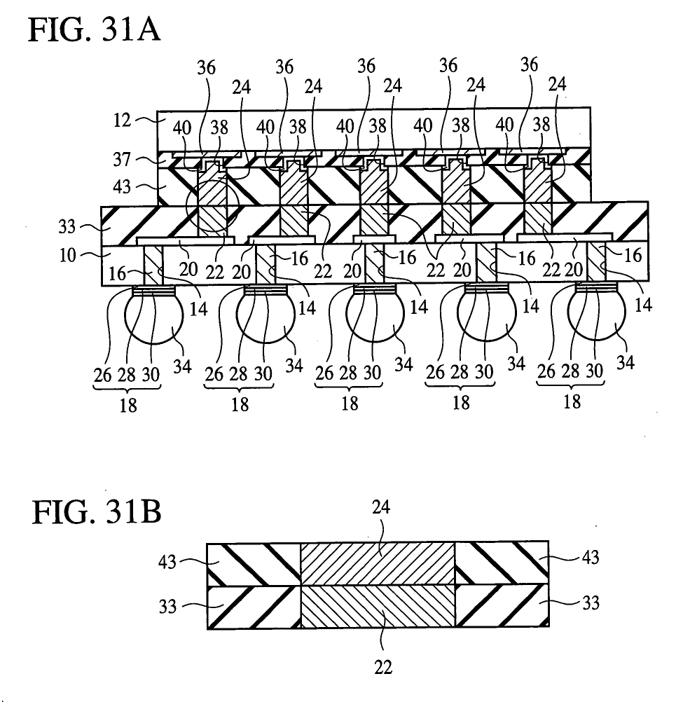

The electronic device according to a second embodiment of the present invention and the method for fabricating the electronic device will be explained with reference to FIGS. 20 to 31B. FIG. 20 is a sectional view of the electronic device according to the present embodiment. The same members of the present embodiment as those of the electronic device according to the first embodiment and the method for fabricating the electronic device illustrated in FIGS. 1 to 19B are represented by the same reference numbers not to repeat or to simplify their explanation.

(The Electronic Device)

First, the electronic device according to the present embodiment will be explained with reference to FIG. 20. FIG. 20 is a sectional view of the electronic device according to the present embodiment.

The electronic device according to the present embodiment is characterized mainly in that a resin layer 33 formed on one primary surface of a circuit substrate 10 (opposed to a semiconductor substrate 12) and a resin layer 43 formed on one primary surface of a semiconductor substrate 12 (opposed to the circuit substrate 10) are formed of a thermosetting resin formed of polyallyl ether as the main component.

As illustrated in FIG. 20, the resin layer 33 is formed on one primary surface of the circuit substrate 10 (opposed to the semiconductor substrate 12), burying electrodes 22.

The resin layer 33 is formed of a resin formed of polyallyl ether as the main component (hereinafter called “polyallyl ether-based resin”). The resin formed of polyallyl ether as the main component is a thermosetting resin which is cured and shrunk without generating by-products, such as water, alcohol, organic acid, nitrides, etc., as is the BCB resin. Such thermosetting resin can be, e.g., a resin (trade name: SiLK) by Dow Chemical Company, or others.

The polyallyl ether-based resin can be cured without generating by-products, such as water, alcohol, etc., as described above. The solvent remaining in the polyallyl ether-based resin is vaporized in advance by thermal processing, whereby no voids are formed due to the vaporization of the solvent. Thus, the use of the polyallyl ether-based resin as the material of the resin layer 33 makes it possible to cure the resin layer 33 without forming voids. The resin layer 33 can be cured without forming voids, which allows the electronic device to have high reliability.

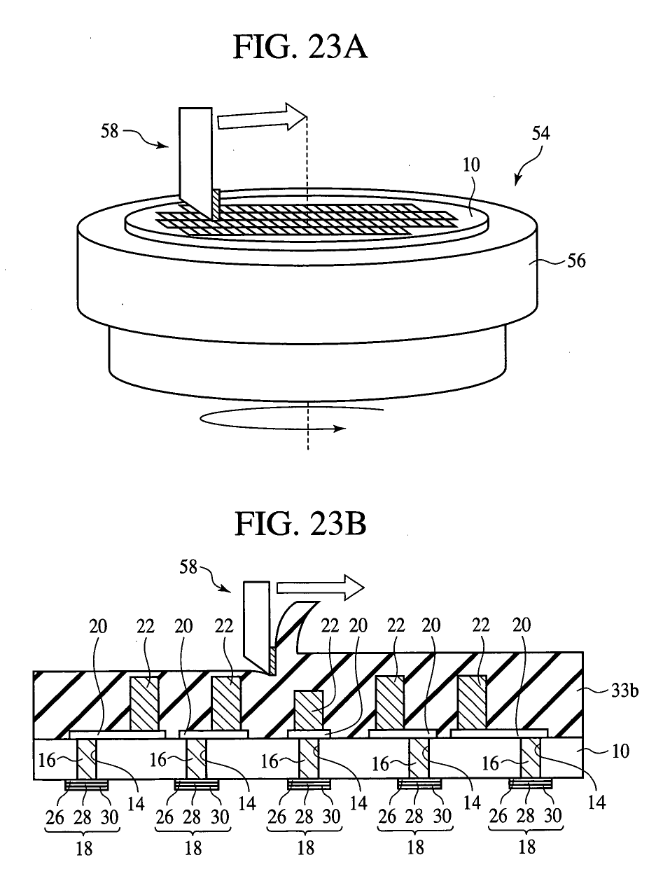

One surfaces of the electrodes 22 (opposed to the surface of the semiconductor substrate 12) and one surface of the resin layer 33 (opposed tot the semiconductor substrate 12) are cut with a cutting tool 58 of diamond or others (see FIGS. 23A and 23B). One surfaces of the electrodes 22 (opposed to the semiconductor substrate 12) and one surface of the resin layer 33 (opposed to the semiconductor substrate 12), which are cut with the cutting tool 58 of diamond or others, are planarized. Specifically, the difference in the height between one surfaces of the electrodes 22 (opposed to the semiconductor substrate 12) and one surface of the resin layer 33 (opposed to the semiconductor substrate 12) is e.g., 100 nm or below.

On one primary surface of the semiconductor substrate 12 (opposed to the circuit substrate 10), the resin layer 43 is formed, burying the electrodes 24.

The resin layer 43 is formed of the polyallyl ether-based resin, as is the resin layer 33. The polyallyl ether-based resin can be, e.g., a polyallyl ether-based resin (trade name: SILK) by Dow Chemical Company, or others, as is the resin layer 33.

As described above, the polyallyl ether-based resin can be cured without generating by-products, such as water, alcohol, etc. As described above, the solvent remaining the polyallyl ether-based resin is vaporized in advance by thermal processing, whereby no void are formed due to the vaporization of the solvent when the polyallyl ether-based resin is cured by thermal processing. The use of the polyallyl ether-based resin as the material of the resin layer 43 makes it possible to form the resin layer 43 without forming voids. The resin layer 43 can be cured without forming voids, which permits the electrodes 22 and the electrodes 24 to be jointed to each other by the shrinkage of the resin layer 33 and the resin layer 43.

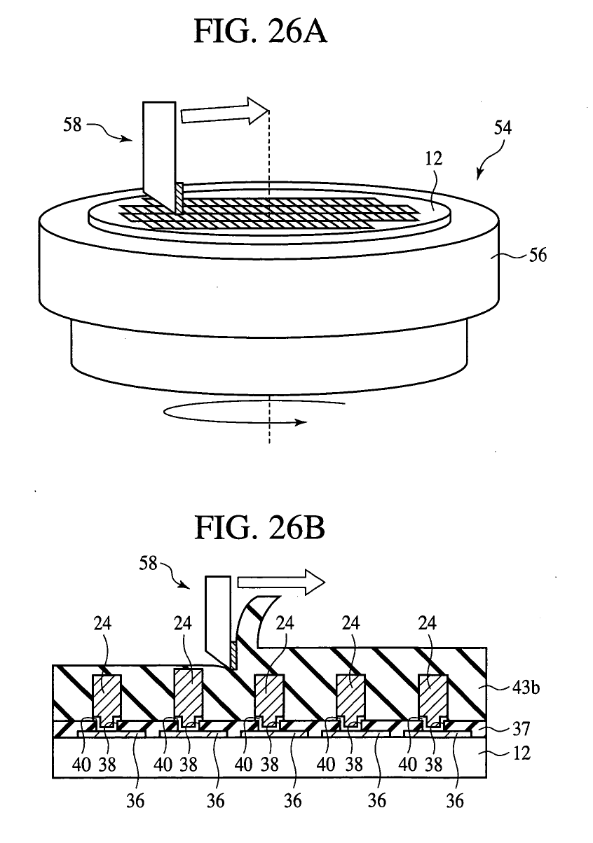

In the illustrated structure, one surfaces of the electrodes 24 (opposed to the surface of the circuit substrate 10) and one surface of the resin layer 43 (opposed to the circuit substrate 10) are cut with the cutting tool 58 of diamond or others (see FIGS. 26A and 26B), as will be described later. One surfaces of the electrodes 24 (opposed to the circuit substrate 10) and one surface of the resin layer 43 (opposed to the circuit substrate 10), which are cut with the cutting tool 58 of diamond or others, are planarized. Specifically, the difference in the height between one surfaces of the electrodes 24 (opposed to the circuit substrate 10) and one surface of the resin layer 43 (opposed to the circuit substrate 10) is e.g., 100 nm or below.

The resin layer 33 formed on the circuit substrate 10 and the resin layer 43 formed on the semiconductor substrate 12 are adhered to each other. The electrodes 22 formed on the circuit substrate 10 and the electrodes 24 formed on the semiconductor substrate 1 are jointed to each other. The resin layer 33 and the resin layer 43 have been subjected to thermal processing for curing and shrinking the resin layer 33 and the resin layer 43. The resin layer 33 and the resin layer 43 are adhered to each other and shrunk, whereby the electrodes 22 and the electrodes 24 are caused to firmly joint to each other by the shrinkage of the resin layer 33 and the resin layer 43.

Thus, the electronic device according to the present embodiment is constituted.

As described above, the material of the resin layers 33, 43 may be the polyallyl ether-based resin. When the resin layers 33, 43 are formed of the polyallyl ether-based resin, the resin layers 33, 43 can be cured and shrunk without generating by-products, such as water, alcohol, etc. The resin layers 33, 43 are formed of a resin which is cured by thermal processing without generating by-products, such as water, alcohol, etc., whereby the resin layers can be cured while preventing the formation of voids in the resin layers. Thus, according to the present embodiment as well, the electrodes 22 and the electrodes 24 can be caused to joint to each other by the shrinkage of the resin layer 33 and the resin layer 43. The electrodes 22 and the electrodes 24 are caused to joint to each other by the shrinkage of the resin layer 33 and the resin layer 43, which makes it possible to joint the electrodes 22 and the electrodes 24 to each other without applying an excessively large pressure. Accordingly, even when fragile inter-layer insulation films are formed on, e.g., the semiconductor substrate 12, the electrodes 22 and the electrodes 24 can be surely jointed to each other without damaging the fragile inter-layer insulation films. Thus, the electronic device according to the present embodiment as well can have the electrodes 22 and the electrodes 24 surely jointed without deteriorating the reliability.

(The Method for Fabricating the Electronic Device)

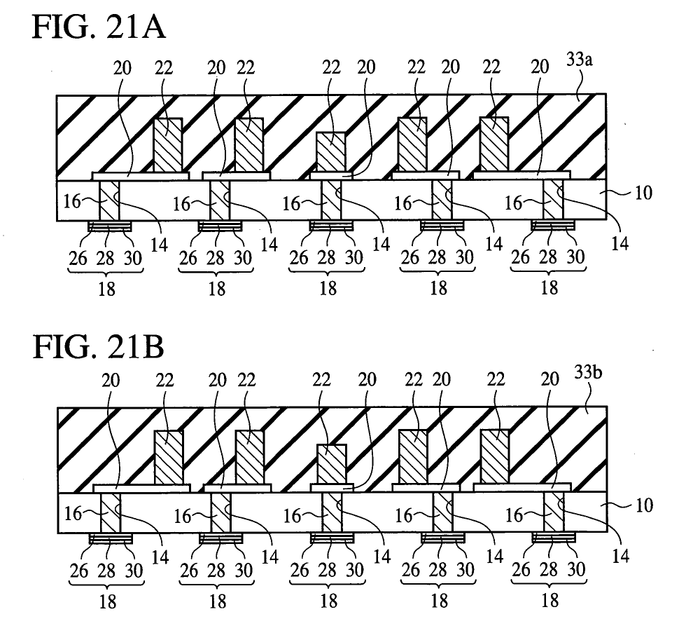

Next, the method for fabricating the electronic device according to the present embodiment will be explained with reference to FIGS. 21A to 31B. FIGS. 21A to 31B are views of the electronic device according to the present embodiment in the steps of the method for fabricating the electronic device, which illustrate the method.

FIGS. 21A to 22B, FIG. 23B to 25B and FIGS. 26B to 31B are sectional views. FIG. 23A and FIG. 26A are perspective views.

First, the step of preparing the circuit substrate 10 to the step of forming interconnections 20 and the electrodes 22 on one primary surface of the circuit substrate 10 (opposed to the circuit substrate 12) including the interconnections 20 and the electrodes 22 forming step are the same as those of the method for fabricating the electronic device according to the first embodiment described above with reference to FIGS. 2A to 4B, and their explanation will not be repeated.

Next, as illustrated in FIG. 21A, a resin layer (a first resin layer) 33a is formed on the entire surface by, e.g., spin coating. The film thickness of the resin layer 33a is, e.g., about 10 μm. The resin layer 33a can be formed of, e.g., the polyallyl ether-based resin. The polyallyl ether-based resin is, e.g., a polyallyl ether-based resin (trade name: SiLK) by Dow Chemical Company, or others. The polyallyl ether-based resin is a thermosetting resin having the curing characteristic that the polyallyl ether-based resin is liquid before the thermal processing, semi-cured as the cure is advanced to some extent by the thermal processing, and is completely cured as the cure is further advanced by the thermal processing. Thermal processing conditions for the polyallyl ether-based resin are 200-250° C. and about 1 hour for the semi-cure and 400-450° C. and about 1 hour for the complete cure.

Thus, the resin layer 33a is formed, burying the electrodes 22. Immediately after the resin layer 33a has been applied, the thermal processing has not yet been made, and the resin layer 33a is liquid.

Next, the thermal processing is made under conditions for semi-curing the resin layer 33a, whereby the non-cured resin layer 33a is cured into the semi-cured resin layer 33b (see FIG. 21B). Preferably, the degree of cure of the resin layer 33b is 40-80%. The degree of cure of the resin layer 33b is 50-60% here. The thermal processing temperature is, e.g., about 200-250° C., and the thermal processing period of time is, e.g., about 1 hour. The surrounding atmosphere for the thermal processing is, e.g., N₂ atmosphere.

The thermal processing conditions are not limited to the above. The thermal processing may be performed under conditions which make the degree of cure of the resin 33b about 40-80%. For example, when the thermal processing temperature is set high, the thermal processing period of time may be set short. The thermal processing period of time may be set long when the thermal processing temperature is set low.

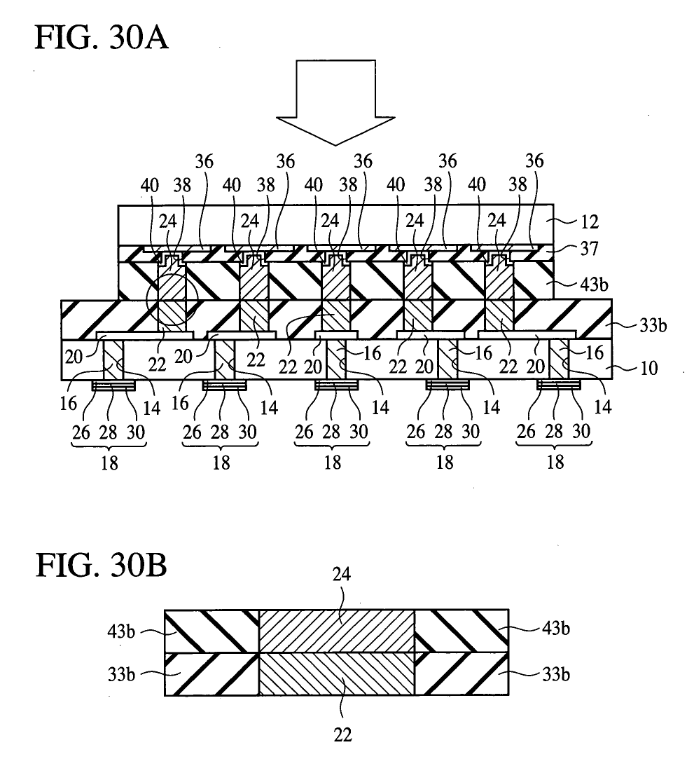

However, the thermal processing temperature must be set at a temperature higher than the boiling point of the solvent of the polyallyl ether-based resin solution. That is, when the thermal processing is made at a temperature lower than the boiling point of the solvent of the polyallyl ether-based resin solution, the solvent of the polyallyl ether-based resin remains in the resin layer 33b. In this case, the solvent remaining in the resin layer 33b is vaporized in the thermal processing of the later step. In the later step thermal processing is made with the resin layer 33b and the resin layer 43b laid the latter on the former (see FIGS. 30A and 30B), and the vaporized solvent is confined in the resin layer 43b. The vaporized solvent confined in the resin layer 33b forms voids in the resin layer 33b. Accordingly, to prevent the formation of voids in the resin layer 33b in the later step thermal processing, the thermal processing temperature must be set at a temperature higher than the boiling temperature of the solvent of the polyallyl ether-based resin solution.

Conditions for the thermal processing are thus set suitably, whereby the degree of cure of the resin layer 33b can be set at 40-80%.

The degree of cure of the resin layer 33b is set at 40-80% for the following reason.

That is, when the degree of cure of the resin layer 33b is set at 40% or below, the resin layer 33b is much shrunk in the later step thermal processing. Then, the resin layer 33b and the resin layer 43b are temporarily adhered to each other in the late step thermal processing but are peeled from each other as the resin layer 43b is shrunk. In this case, the shrinkage of the resin layer 33b and the resin layer 43b cannot cause the electrodes 22 and the electrodes 24 to surely joint to each other. Accordingly, in order to surely adhere the resin layer 33b and the resin layer 43b to each other and surely joint the electrodes 22 and the electrodes 24 to each other, it is necessary to set the degree of cure of the resin layer 33b at 40% or above.

When the degree of cure of the resin layer 33b is set at above 80%, the functional groups present in the resin layer 33b, specifically hydroxyl groups (—OH) are considerably decreased. Such functional groups contribute to adhering the resin layer 33b and the resin layer 43b to each other in the later step. When the functional groups, which contribute to the adhesion are extremely a few, it is difficult to adhere the resin layer 33b and the resin layer 43b to each other in the later step. Furthermore, with the degree of cure of the resin layer 33b is set at above 80%, when the resin layer 33b is cut in the later step, the surface of the resin layer 33b becomes considerably rough. With the surface of the resin layer 33b made considerably rough, it is difficult to adhere the resin layer 33b and the resin layer 43b to each other in the later step. Thus, to surely adhere the resin layer 33b and the resin layer 43b to each other, it is necessary to set the degree of cure of the resin layer 33b at 80% or below.

For the above-described reason, it is preferable to set the degree of cure of the resin layer 33b at 40-80%.

The degree of cure of the resin layer 33b can be given by analyzing the infrared absorption spectra with the Fourier transform infrared spectrophotometer (FT-IR).

When the resin layer 33b is formed of the polyallyl ether-based resin, the hydroxyl groups (—OH) decrease as the cure advances. Accordingly, the degree of cure can be given by measuring intensities of the spectrum components of the infrared absorption spectra, which correspond to the hydroxyl groups.

That is, the resin layer which has not been subjected to the thermal processing is measured by the Fourier transform infrared spectrophotometer (FT-IR) to give infrared absorption spectra for the degree of cure of 0%. The intensity P₇ of the spectrum component of the infrared absorption spectra for the degree of cure of 0%, which corresponds to the hydroxyl groups.

On the other hand, the completely cured resin layer is measured with the Fourier transform infrared spectrophotometer (FT-IR) to obtain the infrared absorption spectra for the degree of cure of 100%. The intensity P₈ of the component of the infrared absorption spectrum for the degree of cure of 100%, which corresponds to the hydroxyl groups is given.

The semi-cured resin layer 33b is measured with the Fourier transform infrared spectrophotometer (FT-IR) to give the infrared absorption spectra of the semi-cured resin layer 33b. The intensity of P₉ of the component of the infrared absorption spectra for the semi-cured resin layer 33b, which corresponds to the hydroxyl groups is given.

Then, the degree of cure S of the semi-cured resin layer 33b is given by
S=[(P₉−P₇)/(P₈−P₇)]×100(%).

The degree of cure of the resin layer 33b is given based on intensities of the spectrum components of the hydroxyl groups here. However, the spectrum component used in computing the degree of cure of the resin layer 33b is not essentially the spectrum component corresponding to the hydroxyl groups.

When the resin layer 33b is formed of the polyallyl ether-based resin, as the cure advances, the hydroxyl groups are decreased while the benzene rings increase. When oxygen (O) bonds with the benzene rings, C—O bonds are formed. Accordingly, intensities of the spectrum components of the infrared absorption spectra, which correspond to the C—O bonds are measured, whereby the degree of cure of the resin layer 33b can be also given.

That is, the resin layer which has not been subjected to the thermal processing is measured by the Fourier transform infrared spectrophotometer (FT-IR) to give infrared absorption spectra for the degree of cure of 0%. The intensity P₁₀ of the spectrum component of the infrared absorption spectra for the degree of cure of 0%, which corresponds to the C—O bonds, is given.

On the other hand, the completely cured resin layer is measured with the Fourier transform infrared spectrophotometer (FT-IR) to obtain the infrared absorption spectra for the degree of cure of 100%. The intensity P₁₁ of the component of the infrared absorption spectrum for the degree of cure of 100%, which corresponds to the C—O bonds is given.

The semi-cured resin layer 33b is measured with the Fourier transform infrared spectrophotometer (FT-IR) to give the infrared absorption spectra of the semi-cured resin layer 33b. The intensity of P₁₂ of the component of the infrared absorption spectra for the semi-cured resin layer 33b, which corresponds to the C—O bonds is given.

Then, the degree of cure S of the semi-cured resin layer 33b is given by
S=[(P₁₀−P₁₂)/(P₁₀−P₁₁)]×100(%).

On the other hand, the step of preparing the semiconductor substrate 12 to the step of forming the electrodes 24, etc. on one primary surface of the semiconductor substrate 12 (opposed to the circuit substrate 10) including the electrodes 24 forming step are the same as those of the method for fabricating the electronic device according to the first embodiment described above with reference to FIG. 6A to FIG. 7B, and their explanation will not be repeated.

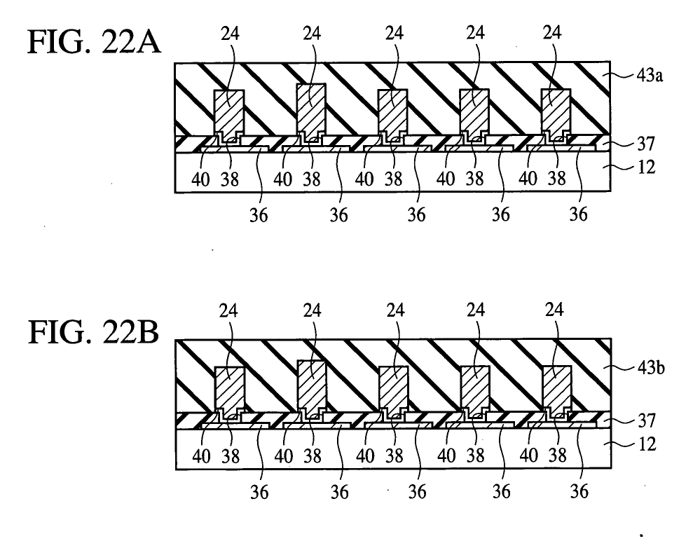

Then, as illustrated in FIG. 22A, the resin layer (the second resin layer) 43a is formed on the entire surface by, e.g., spin coating. The resin layer 43a is formed of, e.g., the polyallyl ether-based resin. The material of the polyallyl ether-based resin can be, e.g., a resin (trade name: SiLK) by Dow Chemical Company. As described above, the polyallyl ether-based resin is a thermosetting resin having the curing characteristic that the resin is liquid before the thermal processing, is semi-cured as the cure advances to some extent by the thermal processing and is completely cured as the thermal processing is further advanced. As described above, thermal processing conditions for semi-curing the polyallyl ether-based resin are 200-250° C. and about 1 hour, and thermal processing conditions for completely curing the polyallyl ether-based resin are 400-450° C. and about 1 hour. The film thickness of the resin layer 43a is, e.g., about 10 μm.

Thus, the resin layer 43a is formed, burying the electrodes 24. Immediately after the resin layer 43a has been applied, the resin layer 43a has not yet been subjected to the thermal processing and is liquid.

Next, the thermal processing is made under conditions for semi-curing the resin layer 43a, whereby the non-cured resin layer 43a is cured into the semi-cured resin layer 43b (see FIG. 22B). Preferably, the degree of cure of the resin layer 43b is 40-80%. The degree of cure of the resin layer 43b is 50-60% here. The thermal processing temperature is, e.g., about 200-250° C., and the thermal processing period of time is, e.g., about 1 hour.

The thermal processing conditions are not limited to the above. The thermal processing may be performed under conditions which make the degree of cure of the resin 43b about 40-80%. For example, when the thermal processing temperature is set high, the thermal processing period of time may be set short. The thermal processing period of time may be set long when the thermal processing temperature is set low.

However, the thermal processing temperature must be set at a temperature higher than the boiling point of the solvent of the polyallyl ether-based resin solution. That is, when the thermal processing is made at a temperature lower than the boiling point of the solvent of the polyallyl ether-based resin solution, the solvent of the polyallyl ether-based resin remains in the resin layer 43b. In this case, the solvent remaining in the resin layer 43b is vaporized in the thermal processing of the later step. In the later step thermal processing is made with the resin layer 43b and the resin layer 43b laid the latter on the former (see FIGS. 30A and 30B), and the vaporized solvent is confined in the resin layer 43b. The vaporized solvent confined in the resin layer 43b forms voids in the resin layer 43b. Accordingly, to prevent the formation of voids in the resin layer 43b in the later step thermal processing, the thermal processing temperature must be set at a temperature higher than the boiling temperature of the solvent of the polyallyl ether-based resin solvent.

Conditions for the thermal processing are thus set suitably, whereby the degree of cure of the resin layer 43b can be set at 40-80%.

The degree of cure of the resin layer 43b is set at 40-80% for the same reason for setting the degree of cure of the resin layer 33b at 40-80%.

That is, when the degree of cure of the resin layer 43b is set at below 40%, the resin layer 43b is much shrunk in the later step thermal processing. Then, the resin layer 33b and the resin layer 43b are temporarily adhered to each other in the later step thermal processing, but as the resin layer 43b is shrunk, the resin layer 33b and the resin layer 43b are separated from each other. In this case, the electrodes 22 and the electrodes 24 cannot be surely jointed to each other. Accordingly, to surely adhere the resin layer 33b and the resin layer 43b to each other while surely jointing the electrodes 22 and the electrodes 24 to each other, it is necessary to set the degree of cure of the resin layer 43b at 40% or above.

When the degree of cure of the resin layer 43b is set at above 80%, the functional groups present in the resin layer 43b, specifically functional groups are considerably decreased. Such functional groups (carbon-carbon double bonds) are present in cyclobutene rings and monomers contained in the resin layer 43b. Such functional groups (carbon-carbon double bonds) contribute to adhering the resin layer 33b and the resin layer 43b to each other when the resin layer 33b and the resin layer 43b are adhered to each other in the later step. When the functional groups, which contribute to the adhesion are extremely a few, it is difficult to adhere the resin layer 33b and the resin layer 43b to each other in the later step. Furthermore, with the degree of cure of the resin layer 43b is set at above 80%, when the resin layer 43b is cut in the later step, the surface of the resin layer 43b becomes considerably rough. With the surface of the resin layer 43b made considerably rough, it is difficult to adhere the resin layer 33b and the resin layer 43b to each other in the later step. Thus, to surely adhere the resin layer 33b and the resin layer 43b to each other, it is necessary to set the degree of cure of the resin layer 43b at 80% or below.

For the above-described reason, it is preferable to set the degree of cure of the resin layer 43b at 40-80%.

The degree of cure of the resin layer 43b can be given by the same method as the method for giving the degree of cure of the resin layer 33b. That is, the degree of cure of the resin layer 43b can be given by analyzing the infrared absorption spectra with the Fourier transform infrared spectrophotometer (FT-IR).

Then, as illustrated in FIG. 23A, the circuit substrate 10 is fixed to a chuck table 56 of an ultra-precision lathe 54 by vacuum suction.

FIG. 23A is a perspective view of the circuit substrate fixed to the ultra-precision lathe. The circuit substrate 10 is fixed to the chuck table 56 at the backside thereof, i.e., the surface where the electrodes 22, etc. are not formed.

Next, as illustrated in FIG. 23B, while the circuit substrate 10 is being rotated, the upper parts of the electrodes 22 and the upper part of the resin layer 33b are cut with the cutting tool 58 of diamond. At this time, the rough cut is continued until the height of one surface of the resin layer 33b (opposed to the resin layer 43b formed on the semiconductor substrate 12) becomes higher by about 5 μm than one primary surface of the circuit substrate 10 (opposed to the semiconductor substrate 12).

Conditions for roughly cutting the upper parts of the electrodes 22 and the upper part of the resin layer 33b are as exemplified below.

The rake of the cutting tool 58 is, e.g., 0 degree. The rake angle is an angle made by a plane perpendicular to the surface of the object-to-be-cut, which is being worked and the forward surface (rake face) of the cutting tool edge in the advancing direction.

The rotation number of the chuck table 56 is, e.g., about 3000 rpm. In this case, the cutting speed is, e.g., about 30 m/second.

The cut amount of the cutting tool 58 is, e.g., about 2-3 μm.

The feed speed of the cutting tool 58 is, e.g., 20 μm/rotation.

The thickness of the resin layer 33b before cut is about 10 μm, but the cut amount by the cutting tool 58 is, e.g., about 2-3 μm. When the cut is made until the height of one surface of the resin layer 33b (opposed to the resin layer 43b formed on the semiconductor substrate 12) becomes higher by about 5 μm than one primary surface of the circuit substrate 10 (opposed to the semiconductor substrate 12), the thickness of the cut part of the resin layer 33b is larger than the cut amount of the cutting tool 58. The upper part of the resin layer 33b is cut a plurality of times to thereby to make the height of one surface of the resin layer 33b (opposed to the resin layer 43b formed on the semiconductor substrate 12) by about 5 μm than one primary surface of the circuit substrate 10 (opposed to the semiconductor substrate 12).

When the upper parts of the electrodes 22 and the upper part of the resin layer 33b are cut with the cutting tool 58, some large force is applied by the cutting too 158 to the electrodes 22 and the resin layer 33b. While the upper part of the resin layer 33b is being cut, a force is applied not only in the direction horizontal to one surface of the resin layer 33b (opposed to the resin layer 43b formed on the semiconductor substrate 12), but also in the direction perpendicular to one surface of the resin layer 33b (opposed to the resin layer 43b formed on the semiconductor substrate 12). Accordingly, the resin layer 33b is cut while being compressed and deformed to some extent. After the cut, the resin layer 33b which has been compressed and deformed is restored to some extent. On the other hand, the electrodes 22, which are formed of a metal, such as Cu or another, are not substantially compressed and deformed while being cut. Accordingly, the height of one surface of the resin layer 33b (opposed to the resin layer 43b formed on the semiconductor substrate 12) after cut is higher than the height of one surfaces of the electrodes 22 (opposed to the electrodes 24 formed on the semiconductor substrate 12) after cut.

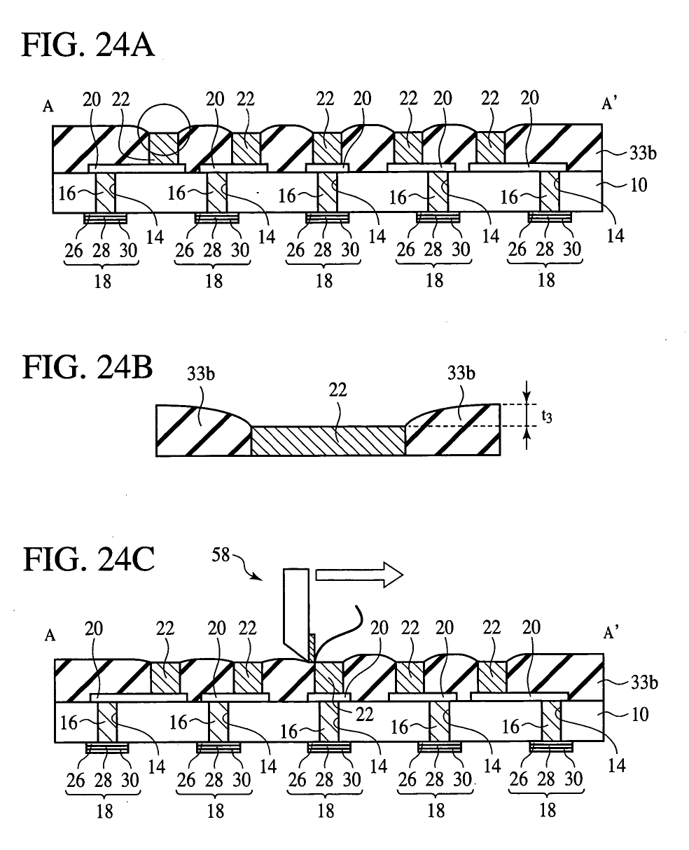

Immediately after the rough cut, as illustrated in FIGS. 24A and 24B, the difference t₃ between the height of one surface of the resin layer 33b (opposed to the resin layer 43b formed on the semiconductor substrate 12) and the height of one surfaces of the electrodes 22 (opposed to the electrodes 24 formed on the semiconductor substrate 12) is about hundreds nm, which is relatively larger.

FIG. 24B is an enlarged sectional view of the part circled in FIG. 24A.

When the difference t₃ between the height of one surface of the resin layer 33b (opposed to the resin layer 43b formed on the semiconductor substrte 12) and the height of one surfaces of the electrodes 22 (opposed to the electrodes 24 formed on the semiconductor substrate 12) is thus relatively large, even though the resin layer 43b is cured and shrunk by the later step thermal processing, one surface of the resin layer 33b (opposed to the resin layer 43b formed on the semiconductor substrate 12) is remains higher than one surfaces of the electrodes 22 (opposed to the electrodes 24 formed on the semiconductor substrate 12), which makes it impossible to joint the electrodes 22 and the electrodes 24 to each other.

To avoid this, the rough cut is followed by finish cut so that the difference t₃ between the height of one surface of the resin layer 33b (opposed to the resin layer 43b formed on the semiconductor substrate 12) and the height of one surfaces of the electrodes 22 (opposed to the electrodes 24 formed on the semiconductor substrate 12) becomes a suitable value.

Conditions for finish cutting the upper parts of the electrodes 22 and the upper part of the resin layer 33b are as exemplified below.

The rake angle of the cutting tool 58, the rotation number of the chuck table 56 and the feed speed of the cutting tool 58 for the finish cut are the same as those for the rough cut of the resin layer 33b. It is not necessary to change this setting for the finish cut, which follows the rough cut.

The cut amount of the cutting tool 58 is, e.g., 0 nm. The cut amount of the cutting tool 58 is set so small, so that the difference t₃ between the height of one surface of the resin layer 33b (opposed to the resin layer 43b formed on the semiconductor substrate 12) and the height of one surfaces of the electrodes 22 (opposed to the surfaces of the electrodes 24 formed on the semiconductor substrate 12) can be suitably small.

However, the cut amount of the cutting tool 58 is not essentially 0 nm. For example, the cut amount of the cutting tool 58 may be set at about 10-100 nm.

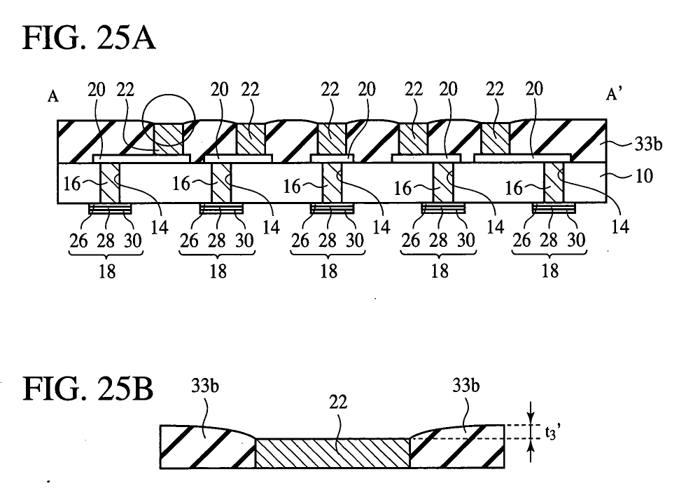

As illustrated in FIGS. 25A and 25B, even the finish cut does not make the difference t₃′ between the height of one surface of the resin layer 33b (opposed to the resin layer 43b formed on the semiconductor substrate 12) and the height of one surfaces of the electrodes 22 (opposed to the surfaces of the electrodes 24 formed on the semiconductor substrate 12) zero. This is because the resin layer 33b is compressed and deformed to some extent in the finish cut, and the resin layer 33b which has been compressed and deformed by the finish cut is restored to some extent.

FIG. 25B is an enlarged sectional view of the circled part in FIG. 25A.

When the compressive modulus of elasticity of the object to be cut is E, the thickness of the object to be cut is L, and a force to be applied perpendicularly to the object-to-be-cut is F, the difference t₃′ between the height of one surface of the resin layer 33b (opposed to the resin layer 43b formed on the semiconductor substrate 12) and the height of one surface of the electrodes 22 (opposed to the electrodes 24 formed on the semiconductor substrate 12) is
t₃′=(F×L)/E.

The difference t₃′ between one surface of the resin layer 33b (opposed to the resin layer 43b formed on the semiconductor substrate 12) and the height of one surfaces of the electrodes 22 (opposed to the electrodes 24 formed on the semiconductor substrate 12) may be suitably set to be in the range of 0-100 nm.

The difference t₃′ between the height of one surface of the resin layer 33b (opposed to the resin layer 43b formed on the semiconductor substrate 12) and the height of one surfaces of the electrodes 22 (opposed to the electrodes 24 formed on the semiconductor substrate 12) is set at 0-100 nm for the following reason.

That is, when the difference t₃′ between one surface of the resin layer 33b (opposed to the resin layer 43b formed on the semiconductor substrate 12) and the height of one surfaces of the electrodes 22 (opposed to the electrodes 24 formed on the semiconductor substrate 12) is above 100 nm, as described above, even the resin layer 33b is cured and shrunk by the later step thermal processing, the height of one surface of the resin layer 33b (opposed to the resin layer 43b formed on the semiconductor substrate 12) is higher than the height of one surfaces of the electrodes 22 (opposed to the electrodes 24 formed on the semiconductor substrate 12), which makes it impossible to joint the electrodes 22 and the electrodes 24 to each other.

On the other hand, the difference t₃′ between the height of one surface of the resin layer 33b (opposed to the resin layer 43b formed on the semiconductor substrate 12) and the height of one surfaces of the electrodes 22 (opposed to the electrodes 24 formed on the semiconductor substrate 12) is below 0 nm, in the later step thermal processing, the resin layer 33b and the resin layer 43b are shrunk before being surely adhered to each other, which makes it difficult to surely adhere the resin layer 33b and the resin layer 43b to each other.

For this reason, it is important that the difference t₃′ between the height of one surface of the resin layer 33b (opposed to the resin layer 43b formed on the semiconductor substrate 12) and the height of one surfaces of the electrodes 22 (opposed to the surfaces of the electrodes 24 formed on the semiconductor substrate 12) is set at 0-100 nm.

To cut the upper part of the resin layer 33b and the upper parts of the electrodes 22 it is important to cut them so that the ten-point height of irregularities Rz of the surface of the resin layer 33b is 0.1 μm or below.

The resin layer 33b is cut so that the ten-point height of irregularities of the surface of the resin layer 33b is 0.1 μm or below, because when the ten-point height of irregularities Rz of the surface of the resin layer 33b is above 0.1 μm, it is not easy to adhere the resin layer 33b and the resin layer 43b to each other in the later step.

To surely adhere the resin layer 33b and the resin layer 43b to each other, it is very important to cut the resin layer 33b so that the ten-point height of irregularities Rz of the surface of the resin layer 33b becomes 0.1 μm or below.

When fins are formed on the electrodes 22 in the cut, there is risk that the fins may short-circuit the neighboring or adjacent electrodes 22.

Accordingly, it is preferable to set the cut conditions suitably not to form fins on the electrodes 22 in the cut.

Thus, the upper parts of the electrodes 22 and the upper part of the resin layer 33b are cut (see FIGS. 25A and 25B).

It is also possible that with the circuit substrate 10 fixed, a wheel (not illustrated) with the cutting tool 58 mounted on is rotated for the cut (not illustrated).

Then, as illustrated in FIG. 16A, the semiconductor substrate 12 is fixed to the chuck table 56 of the ultra-precision lathe 54 by vacuum suction. FIG. 26A is a perspective view of the semiconductor substrate fixed to the ultra-precision lathe.

The semiconductor substrate 12 is fixed to the chuck table 56 at the underside, i.e., the surface of the semiconductor substrate 12 without the electrodes 24, etc. formed on. It is preferable to use a pin chuck (not illustrated) to fix the semiconductor substrate 12 to the chuck table 56.

Then, as illustrated in FIG. 26B, with the semiconductor substrate 12 being rotated, the upper parts of the electrodes 24 and the upper part of the resin layer 43b are cut with the cutting tool 58 of diamond. At this time, the rough cut is made until the height of one surface of the resin layer 43b (opposed to the resin layer 33b formed on the circuit substrate 10) becomes higher by about 5 μm than one primary surface of the semiconductor substrate 12 (opposed to the circuit substrate 10).

Conditions for making the rough cut on the upper parts of the electrodes 24 and the upper part of the resin layer 43b are as exemplified below.

The rake angle of the cutting tool 58 is, e.g., 0 degree.

The rotation number of the chuck table 56 is, e.g., about 2000 rpm. At this time, the cut speed is, e.g., about 20 m/second.

The cut amount of the cutting tool 58 is, e.g., about 2-3 μm/rotation.

The feed speed of the cutting tool 58 is, e.g., 20 μm/rotation.

The film thickness of the resin layer 43b before cut is, e.g., about 10 μm, but the cut amount of the cutting tool 58 is, e.g., about 2-3 μm. When the cut is made until one surface of the resin layer 43b (opposed to the resin layer 33b formed on the circuit substrate 10) is higher by about 5 μm than one primary surface of the semiconductor substrate 12 (opposed to the circuit substrate 10), the thickness of the part of the resin layer 43b to be cut is larger than the cut amount of the cutting tool 58. The upper part of the resin layer 43b is cut a plurality of times to thereby make the height of one surface of the resin layer 43b (opposed to the resin layer 33b formed on the circuit substrate 10) higher by about 5 μm than one primary surface of the semiconductor substrate 12 (opposed to the circuit substrate 10).

When the upper parts of the electrodes 24 and the upper part of the resin layer 43b are cut, a considerably large force is applied to the electrodes 24 and the resin layer 43b by the cutting tool 58. While the upper part of the resin layer 43b is being cut, the force is applied not only horizontally to one surface of the resin layer 43b (opposed to the resin layer 33b formed on the circuit substrate 10), but also vertically to one surface of the resin layer 43b (opposed to the resin layer 33b formed on the circuit substrate 10). Accordingly, the resin layer 43b is cut, compressed and deformed to some extent. After the cut, the resin layer 43b which has been compression deformed by the cutting tool in the cut is restored so some extent. On the other hand, the electrodes 24, which are formed of a metal, such as Cu or others, are not substantially compression deformed. Accordingly, one surface of the resin layer 43b (opposed to the resin layer 33b formed on the circuit substrate 10) after cut becomes higher than the surface of one surfaces of the electrodes 24 (opposed to the electrodes 22 formed on the circuit substrate 10) after cut.

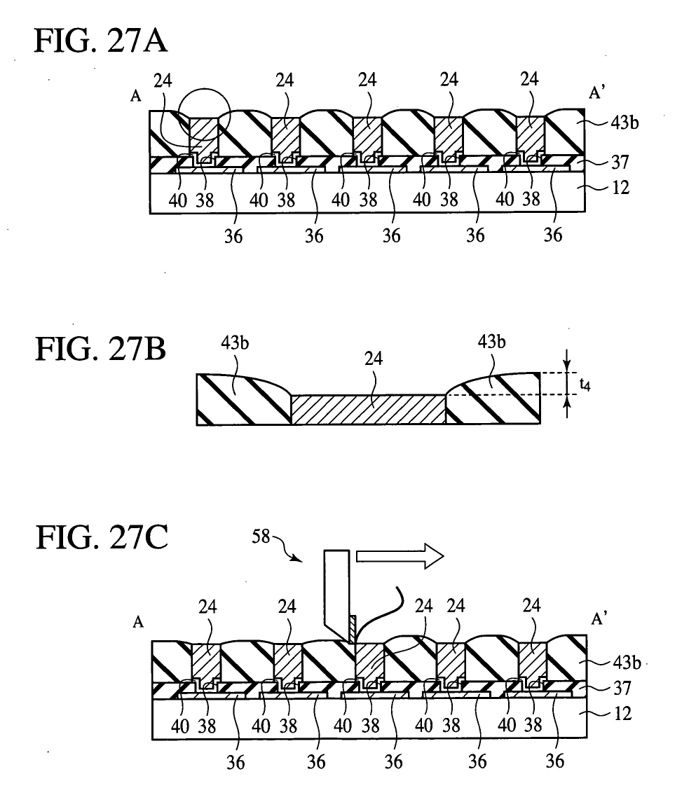

Immediately after the rough cut, as illustrated in FIGS. 27A and 27B, the difference t₄ between the height of one surface of the resin layer 43b (opposed to the resin layer 33b formed on the circuit substrate 10) and the height of one surfaces of the electrodes 24 (opposed to the electrodes 22 formed on the circuit substrate 10) becomes relatively larger by about hundreds nm.

FIG. 27B is an enlarged sectional view of the circled part in FIG. 27A.

When the difference t₄ between the height of one surface of the resin layer 43b (opposed to the resin layer 33b formed on the circuit substrate 10) and the height of one surfaces of the electrodes 24 (opposed to the electrodes 22 formed on the circuit substrate 10) is such relatively large, even when the resin layer 43b is cured and shrunk by the later step thermal processing, the height of one surface of the resin layer 43b (opposed to the resin layer 33b formed on the circuit substrate 10) remains higher than the height of one surfaces of the electrodes 24 (opposed to the electrodes 22 formed on the circuit substrate 10), which makes it impossible to joint the electrodes 22 and the electrodes 24 to each other.

To avoid this, the rough cut is followed by the finish cut so that the difference t₄ between the height of one surface of the resin layer 43b (opposed to the resin layer 33b formed on the circuit substrate 10) and the height of one surfaces of the electrodes 24 (opposed to the electrodes 22 formed on the circuit substrate 10) can be a suitable value (see FIG. 27C).

Conditions for the finish cut for the upper parts of the electrodes 24 and the upper part of the resin layer 43b are as exemplified below.

For the finish cut, the rake angle of the cutting tool 58, the rotation number of the chuck table 56 and the feed speed of the cutting tool 58 are the same as those for the rough cut of the resin layer 43b. The finish cut follows the rough cut, and the setting does not have to be changed.

The cut amount of the cutting tool 58 is, e.g., 0 nm. The cut amount is set so low so that the difference t₄ between the height of one surface of the resin layer 43b (opposed to the resin layer 33 formed on the circuit substrate 10) and the height of one surfaces of the electrodes 24 (opposed to the electrodes 22 formed on the circuit substrate 10) is made suitably small.

The cut amount of the cutting tool 58 is not essentially limited to 0 nm. For example, the cut amount of the cutting tool 58 may be set at about 10-100 nm.

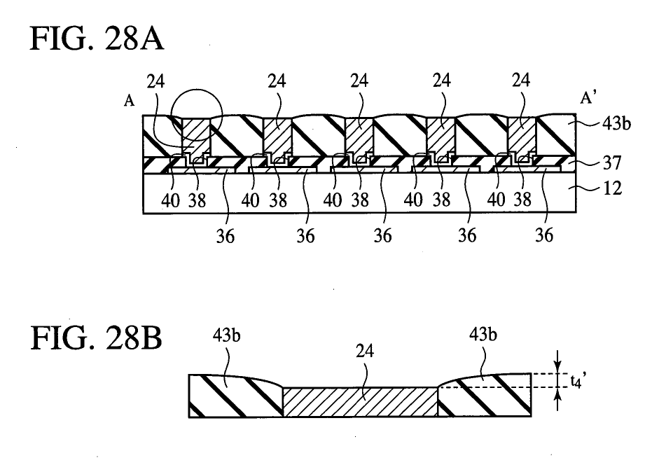

As illustrated in FIGS. 28A and 28B, even the finish cut does not make zero the difference t₄′ between the height of one surface of the resin layer 43b (opposed to the resin layer 33b formed on the circuit substrate 10) and the height of one surfaces of the electrodes 24 (opposed to the electrodes 22 formed on the circuit substrate 10). This is because also in the finish cut, the resin layer 43b is compressed and deformed to some extent, and the resin layer 43b which has been compressed and deformed in the finish cut is restored to some extent after the cut.

FIG. 28B is an enlarged sectional view of the part circled in FIG. 28A.

When the compressive modulus of elasticity of the object to be cut is E, the thickness of the object to be cut is L, and a force to be applied perpendicularly to the object-to-be-cut is F, the difference t₄′ between the height of one surface of the resin layer 43b (opposed to the resin layer 33b formed on the circuit substrate 10) and the height of one surface of the electrodes 24 (opposed to the electrodes 22 formed on the circuit substrate 10) is
t₄′=(F×L)/E

The difference t₄′ between the height of one surface of the resin layer 43b (opposed to the resin layer 33b formed on the circuit substrate 10) and the height of one surfaces of the electrodes 24 (opposed to the electrodes 22 formed on the circuit substrate 10) may be suitably set to be in the range of 0-100 nm.

The difference t₄′ between the height of one surface of the resin layer 43b (opposed to the resin layer 33b formed on the circuit substrate 10) and the height of one surfaces of the electrodes 24 (opposed to the electrodes 22 formed on the circuit substrate 10) is set at 0-100 nm for the following reason.

That is, when the difference t₄′ between one surface of the resin layer 43b (opposed to the resin layer 33b formed on the circuit substrate 10) and the height of one surfaces of the electrodes 24 (opposed to the electrodes 22 formed on the circuit substrate 10) is above 100 nm, as described above, even the resin layer 43b is cured and shrunk by the later step thermal processing, the height of one surface of the resin layer 43b (opposed to the resin layer 33b formed on the circuit substrate 10) is larger than the height of one surfaces of the electrodes 24 (opposed to the electrodes 22 formed on the circuit substrate 10), which makes it impossible to joint the electrodes 42 and the electrodes 22 to each other.

On the other hand, the difference t₄′ between the height of one surface of the reason layer 43b (opposed to the resin layer 33b formed on the circuit substrate 10) and the height of one surfaces of the electrodes 24 (opposed to the electrodes 22 formed on the circuit substrate 10) is below 0 nm, in the later step thermal processing, the resin layer 33b and the resin layer 43b are shrunk before being surely adhered to each other, which makes it difficult to surely adhere the resin layer 33b and the resin layer 43b to each other.

For this reason, it is important that the difference t₄′ between the height of one surface of the resin layer 43b (opposed to the resin layer 33b formed on the circuit substrate 10) and the height of one surfaces of the electrodes 24 (opposed to the surfaces of the electrodes 22 formed on the circuit substrate 10) is set at 0-100 nm.

To cut the upper part of the resin layer 43b and the upper parts of the electrodes 24 it is important to cut them so that the ten-point height of irregularities Rz of the surface of the resin layer 43b is 0.1 μm or below.

The resin layer 43b is cut so that the ten-point height of irregularities Rz of the surface of the resin layer 43b is 0.1 μm or below, because when the ten-point height of irregularities Rz of the surface of the resin layer 43b is above 0.1 μm, it is not easy to adhere the resin layer 33b and the resin layer 43b to each other in the later step.

To surely adhere the resin layer 33b and the resin layer 43b to each other, it is very important to cut the resin layer 43b so that the ten-point height of irregularities Rz of the surface of the resin layer 43b becomes 0.1 μm or below.

When fins are formed on the electrodes 24 in the cut, there is risk that the fins may short-circuit the neighboring or adjacent electrodes 24.

Accordingly, it is preferable to set the cut conditions suitably not to form fins on the electrodes 24 in the cut.

Thus, the upper parts of the electrodes 24 and the upper part of the resin layer 43b are cut (see FIGS. 28A and 28B).

It is also possible that with the semiconductor substrate 12 fixed, a wheel (not illustrated) with the cutting tool 58 mounted on is rotated for the cut (not illustrated).

Next, the circuit substrate 10 is cut in a prescribed size with a thin blade of diamond particles, etc. connected with a binder (not illustrated).

The semiconductor substrate 12 is cut in a chip size with a thin blade of diamond particles, etc. connected with a binder (not illustrated).

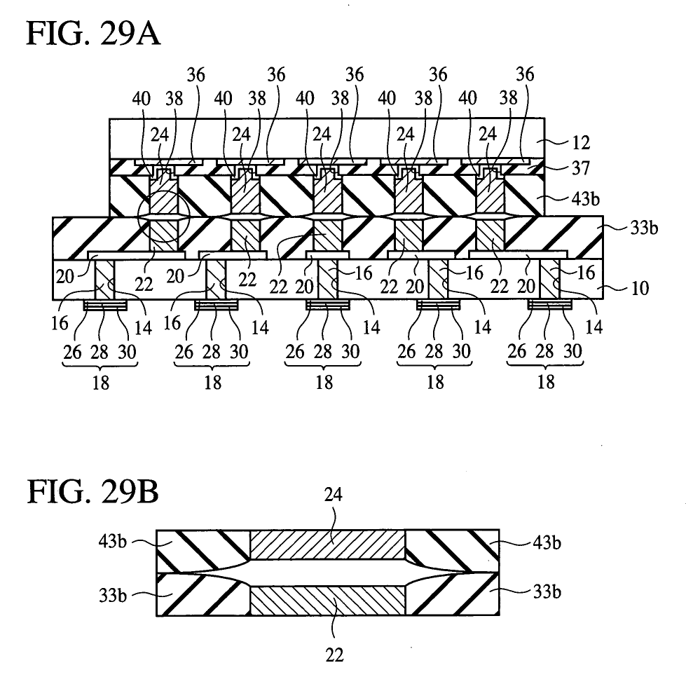

Next, as illustrated in FIGS. 29A and 29B, the semiconductor substrate 12 and the circuit substrate 10 are opposed to each other. At this time, the semiconductor substrate 12 and the circuit substrate 10 are opposed to each other with the electrodes 24 of the semiconductor substrate 12 and the electrodes 22 of the circuit substrate 10 opposed to each other. FIG. 29B is an enlarged sectional view of the part circled in FIG. 29A.

Then, thermal processing is performed with the electrodes 24 of the semiconductor substrate 12 and the electrodes 22 of the circuit substrate 10, and the resin layer 43b of the semiconductor substrate 12 and the resin layer 33b of the circuit substrate 10 being in tight contact respectively with each other by a pressure applied to the circuit substrate 10 and to the semiconductor substrate 12 from the outside (see FIGS. 30A and 30B). An oven (thermal processing apparatus), for example, is used for the thermal processing. The thermal processing temperature is, e.g., 400-450° C. The thermal processing period of time is, e.g., about 1 hour. The pressure is, e.g., about 10 kPa. The thermal processing under these conditions surely adheres the resin layer 33b and the resin layer 43b to each other. The resin layer 33b and the resin layer 43b are respectively shrunk. The resin layer 33b and the resin layer 43b are brought into contact with each other while being respectively shrunk, and the shrinkage of the resin layer 33b and the resin layer 43b causes the electrodes 22 and the electrodes 24 to tightly contact with each other. The semi-cured resin layers 33b, 43b become completely cured resin layers 33, 43. Because of the completely cured resin layers 33, 43, which have been sufficiently shrunk, the electrodes 22 and the electrodes 24 are never separated from each other even when the application of the pressure is stopped.

The electrodes 22 and the electrodes 24 are caused to tightly contact with each other by the shrinkage of the resin layers 33, 43, which makes it unnecessary to apply large pressured to the circuit substrate 10 and the semiconductor substrate 12 from the outside. Accordingly, even when fragile inter-layer insulation films are formed on, e.g., the semiconductor substrate 12, the electrodes 22 and the electrodes 24 can be adhered to each other without damaging the fragile inter-layer insulation films.

The thermal processing temperature is set at 400-450° C., and the thermal processing period of time is set at 1 hour, here. However, the thermal processing temperature and the thermal processing period of time are not limited to them. When the thermal processing temperature is set high, the thermal processing period of time may be short. When the thermal processing temperature is set low, the thermal processing period of time may be long.

However, when the thermal processing temperature is set high, the resin layers 33, 43 do not have often good film quality. When the thermal processing temperature is set low, the thermal processing takes a longtime. When the film quality of the resin films 33, 43, throughputs, etc. are considered, preferably, the thermal processing temperature is set at about 400-450° C., and the thermal processing period of time is set at about 1 hour.

The pressure applied to the circuit substrate 10 and to the semiconductor substrate 12 is set at about 10 kPa here. However, the pressure to be applied to the circuit substrate 10 and to the semiconductor substrate 12 is not limited to about 10 kPa. The pressure may be set suitably at a pressure in the range of 1 kPa-100 kPa.

Then, the solder bumps 34 of, e.g., Sn-based solder are formed on one surfaces of the outside connection electrodes 18 (opposite to the surface opposed to the semiconductor substrate 12) (see FIGS. 19A and 19B). Thus, the electronic device according to the present embodiment is fabricated.

The method for fabricating the electronic device according to the present embodiment is characterized mainly in that the polyallyl ether-based resin is used as the material of the resin layer 33b and the resin layer 43b.

As described above, the polyallyl ether-based resin is a thermosetting resin which is cured without generating by-products, such as water, alcohol, etc. Accordingly, according to the present embodiment as well, the semi-cured resin layers 33b, 43b can be made the completely cured resin layers 33, 43 while the formation of voids in the resin layers 33b, 43b is prevented. According to the present embodiment, the resin layers 33b, 43b never have the volume increased by voids, whereby the resin layers 33b, 43b can be caused to surely shrink. Thus, according to the present embodiment, the electrodes 22 and the electrodes 24 can be caused to surely joint to each other by the shrinkage of the resin layers 33b, 43b. According to the present embodiment, the electrodes 22 and he electrodes 24 are caused to joint to each other by the shrinkage of the resin layer 33b and the resin layer 43b, which permits the electrodes 22 and the electrodes 24 to be surely jointed without the application of an extremely high pressure from the outside. Thus, even when fragile inter-layer insulation films are formed on, e.g., the semiconductor substrate 12, the electrodes 22 and the electrodes 24 can be surely jointed to each other without damaging the fragile inter-layer insulation film. The electronic device according to the present embodiment as well can have the electrodes 22 and the electrodes 24 surely jointed to each other without deteriorating the reliability.

### Modified Embodiments

The present invention is not limited to the above-described embodiments and can cover other various modifications.

For example, in the above-described embodiments, the circuit substrate 10 which has been cut in a prescribed size, and the semiconductor substrate 12 which has been cut in a chip size are laid the former on the latter. The circuit substrate 10 and the semiconductor substrate 12 may not be essentially cut respectively before the circuit substrate 10 and the semiconductor substrate 12 are laid the latter on the former. For example, the circuit substrate 10 and the semiconductor substrate 12 which have not been cut may be laid the latter on the former. It is possible that the semiconductor substrate 12 alone cut in a chip size, and the circuit substrate 10 and the semiconductor substrate 12 are laid the latter on the former.

In the above-described embodiments, a first semi-cured resin layer and a second semi-cured resin layer are adhered to each other. However, at least one of the resin layers to be adhered to each other may be completely cured. For example, the first completely cured resin layer and the second semi-cured resin layer can be adhered to each other. In this case, preferably, the first resin layer is completely cured by the thermal processing, and then the first completely cured resin layer is cut with the cutting tool. When the first resin layer which has been cut with the cutting tool is completely cured, the first resin layer is much shrunk, which hinders the contact between the first resin layer and the second resin layer in the later step, with the result that the first resin layer and the second resin layer cannot be adhered to each other. The first semi-cured resin layer and the second completely cured resin layer may be adhered to each other. In this case, preferably the second completely cured resin layer is cut with the cutting tool after the second resin layer has been completely cured by the thermal processing. When the second resin layer which has been cut with the cutting tool is completely cured, the second resin layer is much shrunk, which hinders the contact between the first resin layer and the second resin layer in the later step, with the result that the first resin layer and the second resin layer cannot be adhered to each other. From the viewpoint that the first resin layer and the second resin layer are surely adhered to each other to thereby ensure a sufficient yield, it is preferable to adhere the first semi-cured resin layer and the second semi-cured resin layer. This is because the semi-cured resin layers can be easily adhered to each other.

What is claimed is:

1. An electronic device comprising:
a first substrate;
a first electrode formed on one primary surface of the first substrate;
a first resin layer of a thermosetting resin formed on said one primary surface of the first substrate, burying the first electrode;
a second substrate opposed to said one primary surface of the first substrate;
a second electrode formed on one primary surface of the second substrate opposed to the first substrate, corresponding to the first electrode and jointed to the first electrode; and
a second resin layer of a thermosetting resin formed on said one primary surface of the second substrate, burying the second electrode and adhered to the first resin layer.

2. An electronic device according to claim 1, wherein
the first resin layer and the second resin layer generate no by-product.

3. An electronic device according to claim 2, wherein
the by-product is water, alcohol organic acid or nitride.

4. An electronic device according to claim 1, wherein
the first resin layer and the second resin layer are formed of a resin containing benzocyclobutene as a main component.

5. An electronic device according to claim 1, wherein
the first resin layer and the second resin layer are formed of a resin containing polyallyl ether as a main component.

6. A method for fabricating an electronic device comprising the steps of:
forming a first electrode on one primary surface of the first substrate;
forming a first resin layer of a thermosetting resin on said one primary surface of the first substrate, burying the first electrode;
cutting an upper part of the first electrode and an upper part of the first resin layer with a cutting tool;
forming a second electrode on one primary surface of the second substrate, corresponding to the first electrode;
forming a second resin layer of a thermosetting resin on said one primary surface of the second substrate, burying the second electrode;
cutting an upper part of the second electrode and an upper part of the second resin layer with a cutting tool;
making thermal processing with the first resin layer and the second resin layer in tight contact with each other, adhering the first resin layer and the second resin layer to each other and shrinking the first resin layer and the second resin layer to thereby joint the first electrode and the second electrode to each other.

7. A method for fabricating an electronic device according to claim 6, wherein
in the step of forming a first resin layer, the first resin layer is formed of a thermosetting resin which is cured without generating a by-product, and
in the step of forming a second resin layer, the second resin layer is formed of a thermosetting resin which is cured without generating a by-product.

8. A method for fabricating an electronic device according to claim 7, wherein
the by-product is water, alcohol, organic acid or nitride.

9. A method for fabricating an electronic device according to claim 6, wherein
the first resin layer and the second resin layer are formed of a resin containing benzocyclobutene as a main component.

10. A method for fabricating an electronic device according to claim 6, wherein
the first resin layer and the second resin layer are formed of a resin containing polyallyl ether as a main component.

11. A method for fabricating an electronic device according to claim 6, further comprising, after the step of forming a first resin layer and before the step of cutting an upper part of the first electrode and an upper part of the first resin layer,
the first thermal processing step of making thermal processing on the first resin layer.

12. A method for fabricating an electronic device according to claim 11, wherein
in the first thermal processing step, the first resin layer is semi-cured.

13. A method for fabricating an electronic device according to claim 12,
in the first thermal processing step, the thermal processing is made so that a degree of cure of the first resin layer becomes 40-80%.

14. A method for fabricating an electronic device according to claim 11, wherein
in the first thermal processing step, the thermal processing is made at a temperature higher than a boiling point of a solvent of a material of the first resin layer.

15. A method for fabricating an electronic device according to claim 6, further comprising, after the step of forming a second resin layer and before the step of cutting an upper part of the second electrode and an upper part of the second resin layer with a cutting tool,
the second thermal processing step of making thermal processing on the second resin layer.

16. A method for fabricating an electronic device according to claim 15, wherein
in the second thermal processing step, the second resin layer is semi-cured.

17. A method for fabricating an electronic device according to claim 16, wherein
in the second thermal processing step, the thermal processing is made so that a degree of cure of the second resin layer becomes 40-80%.

18. A method for fabricating an electronic device according to claim 15,
in the second thermal processing step, the thermal processing is made at a temperature higher than a boiling point of a solvent of a material of the second resin layer.

19. A method for fabricating an electronic device according to claim 6, wherein
in the step of cutting an upper part of the first electrode and an upper part of the first resin layer with the cutting tool, the upper part of the first electrode and the upper part of the first resin layer are cut so that the upper surface of the first resin layer is higher by 0-100 nm than the upper surface of the first electrode.

20. A method for fabricating an electronic device according to claim 6, wherein
in the step of cutting an upper part of the second electrode and an upper part of the second resin layer with the cutting tool, the upper part of the second electrode and the upper part of the second resin layer are cut so that the upper surface of the second resin layer is higher by 0-100 nm than the upper surface of the second electrode.
